(19) United States
(12) Patent Application Publication
(10) Pub. No.: US 2016/0204348 A1
(43) Pub. Date: Jul. 14, 2016

(54) SEMICONDUCTING POLYMERS AND TERNARY BLENDS THEREOF

(71) Applicant: THE UNIVERSITY OF CHICAGO, Chicago, IL (US)

(72) Inventors: Luping YU, Chicago, IL (US); Luyao LU, Chicago, IL (US); Tao XU, Chicago, IL (US)

(21) Appl. No.: 14/610,937

(22) Filed: Jan. 30, 2015

Related U.S. Application Data
(60) Provisional application No. 62/033,802, filed on Aug. 6, 2014.
(60) Provisional application No. 61/934,558, filed on Jan. 31, 2014.

(51) Int. Cl. H01L 51/00; C08G 61/12

(52) U.S. Cl. CPC H01L 51/0036; C08G 61/126; H01L 51/0047; H01L 51/4253

(57) ABSTRACT

Semiconducting photovoltaic polymers and compositions are disclosed. The polymers and compositions exhibit increased power conversion efficiency in solar cells and other applications.

### GOVERNMENT LICENSE RIGHTS

This invention was made with Government support under Grant No. NSF CHE-1229089, awarded by the National Science Foundation and the Air Force Office of Scientific Research, Grant No. FA9550-12-1-0061, awarded by the Air Force Office of Scientific Research, and Grant No. DE-SC0001059 awarded by the U.S. Department of Energy, Office of Science, and Office of Basic Energy Sciences. The Government may have certain rights to this invention.

### TECHNICAL FIELD

This disclosure relates to semiconducting polymers and compositions based on semiconducting polymers. This disclosure also relates to their use in electro-optical and electronic devices.

### BACKGROUND

Bulk heterojunction (BHJ) polymer solar cells (PSCs) are envisioned as promising candidates for providing low cost, light weight and flexible devices to harvest solar energy. Bulk hetero-junction organic solar cells are complex systems. A synergistic approach is needed to optimize their performance. Significant progress has been made in the field of the development of new polymeric structures, optimization of processing conditions and innovation of new device architecture. A key challenge of the development of organic photovoltaic devices is obtaining a predictive understanding of the relationship between polymeric structure of the donor material and device performance. Among the factors that may influence solar energy conversion, the nature of electron donating and accepting materials and the morphology of the composites play crucial roles in determining the final performance of the devices.

In recent years, fullerene derivatives such as [6,6]-phenyl C₇₁-butyric acid methyl ester (PC₇₁BM) have been widely adopted as electron acceptors due to their low lying energy levels and relatively high electron affinity and mobility. It was also found that addition of a small amount of high boiling point solvent, generally 1,8-diiodooctane (DIO), can reliably improve the morphology of most of the composite systems.

Numerous factors can influence the optical and electrical properties of low bandgap polymers. For example, the calculated internal dipole moment change between the ground and excited states of a polymer's repeating units, Δμ_{ge}, has shown a linear correlation with solar cell performance when other factors, such as morphology and charge carrier mobility, are comparable.

Extensive research efforts with the aim to increase power conversion efficiency (PCE) of polymer solar cells have been conducted, such as developing new p-type low band gap polymers with improved properties, optimization of device morphology, usage of effective interlayers, and invention of new device structures. Recently, power conversion efficiencies of binary polymer:fullerene single junction solar cells have reached 9%. Despite the significant improvements achieved for polymer solar cells in the last decade, however, the photovoltaic performance of those cells is still limited by many factors. Those factors include insufficient light absorption and low charge carrier mobility. As a consequence, the maximum power conversion efficiency of a binary polymer solar cell is limited to 10-12%.

Ternary blend polymer solar cells with two donor materials and one fullerene acceptor may overcome the limiting factor for binary devices while maintaining the simplicity of processing conditions using a single active layer compared to tandem cells. Recently, dye sensitizers, polymer sensitizers, small molecular sensitizers and quantum dot sensitizers have been utilized as the additional donor material in ternary blend solar cells to extend the absorption of solar spectrum. Most of these systems are based on poly(3-hexylthiophene) (P3HT) as the dominating donor polymer. In some cases, the device performance is reduced due to the third component acting as recombination centers or from defects within the active layer. It has been reported that adding poly(cyclopentadithiophene-alt-benzothiadiazole) (PCPDTBT) into poly(3-hexylthiophene) (P3HT):phenyl-C₆₁-butyric acid methyl ester (PCBM) blend would lead to decrease crystallinity of PCBM or smooth surface morphology.

### BRIEF SUMMARY

In one aspect, a polymer is of formula (I)

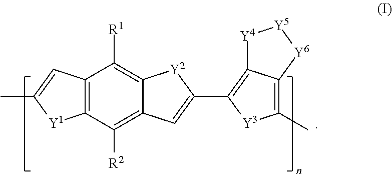

Y¹, Y², Y³, Y⁴, Y⁵, and Y⁶ are independently selected from the group consisting of O, S, Se, NR³, S(O), S(O)₂, CR⁴R⁵ and C(O). R¹, R², R³, R⁴ and R⁵ are independently selected from the group consisting of hydrogen, halogen, unsubstituted or substituted alkyl, unsubstituted or substituted alkoxy, unsubstituted or substituted aryl, unsubstituted or substituted aryloxy, unsubstituted or substituted heteroaryl, and unsubstituted or substituted heteroaryloxy, and the value of n is an integer greater than 0.

In another aspect, a composition comprises an electron-withdrawing material, a polymer of formula (I), and an electron-donating polymer.

In some embodiments, R¹ and R² are independently C₁₋₃₀ alkoxy. In some embodiments, R¹ and R² are independently 2-ethylhexyloxy. In some embodiments, Y¹, Y², and Y³ are independently S. In some embodiments, Y⁴ is S(O)₂. In some embodiments, Y⁵ is NR³. In some embodiments, R³ is C₁₋₃₀ alkyl. In some embodiments, R³ is 2-ethylhexyl. In some embodiments, R³ is octyl. In some embodiments, Y⁶ is C(O).

In one aspect, a polymer is of formula (II):

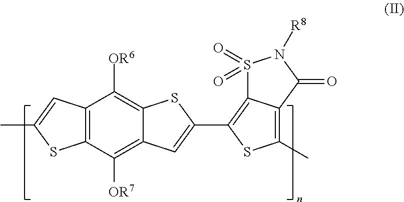

wherein R⁶, R⁷, and R⁸ are independently selected from the group consisting of hydrogen, unsubstituted or substituted alkyl, and unsubstituted or substituted aryl; and n is an integer greater than 0.

In some embodiments, R⁶, R⁷, and R⁸ are independently C₁₋₃₀ alkyl. In some embodiments, R⁶, R⁷, and R⁸ are independently 2-ethylhexyl. In some embodiments, R⁸ is octyl.

In one aspect, a composition is disclosed having an electron-withdrawing material, an electron-donating polymer, and a polymer of formula (I):

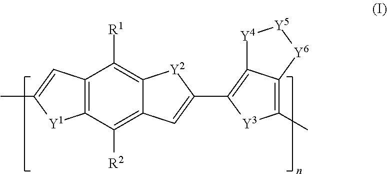

wherein Y¹, Y², Y³, Y⁴, Y⁵, and Y⁶ are independently selected from the group consisting of O, S, Se, NR³, S(O), S(O)₂, CR⁴R⁵ and C(O); R¹, R², R³, R⁴ and R⁵ are independently selected from the group consisting of hydrogen, halogen, unsubstituted or substituted alkyl, unsubstituted or substituted alkoxy, unsubstituted or substituted aryl, unsubstituted or substituted aryloxy, unsubstituted or substituted heteroaryl, and unsubstituted or substituted heteroaryloxy; and n is an integer greater than 0.

In some embodiments, R¹ and R² are independently C₁₋₃₀ alkoxy. In some embodiments, R¹ and R² are independently 2-ethylhexyloxy. In some embodiments, Y¹, Y², and Y³ are independently S. In some embodiments, Y⁴ is S(O)₂. In some embodiments, Y⁵ is NR³. In some embodiments, R³ is C₁₋₃₀ alkyl. In some embodiments, R³ is 2-ethylhexyl. In some embodiments, R³ is octyl. In some embodiments, Y⁶ is C(O).

In some embodiments, the ratio of the polymer of formula (I) and the electron-donating polymer to the electron-withdrawing material to is in a range of about 1:0.5 to about 1:4. In some embodiments, the ratio of the polymer of formula (I) and the electron-donating polymer to the electron-withdrawing material to is in a range of about 1:1 to about 1:4. In some embodiments, the ratio of the polymer of formula (I) and the electron-donating polymer to the electron-withdrawing material is about 1:1.5.

In some embodiments, the polymer of formula (I) is further characterized as formula (II):

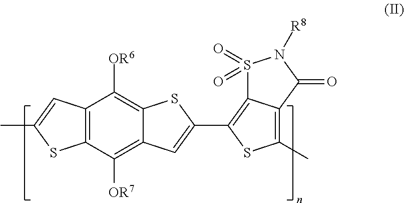

wherein R⁶, R⁷, and R⁸ are independently selected from the group consisting of hydrogen, unsubstituted or substituted alkyl, and unsubstituted or substituted aryl; and n is an integer greater than 0.

In some embodiments, R⁶, R⁷, and R⁸ are independently C₁₋₃₀ alkyl. In some embodiments, R⁶, R⁷, and R⁸ are independently 2-ethylhexyl. In some embodiments, R⁸ is octyl. In some embodiments, the electron-withdrawing material is a fullerene derivative. In some embodiments, the electron-withdrawing material is a C₆₀-C₉₀ fullerene derivative. In some embodiments, the electron-withdrawing material is selected from the group consisting of [6,6]-phenyl-C₆₁-butyric acid methyl ester (PC₆₁BM), [6,6]-phenyl-C₇₀-butyric acid methyl ester (PC₇₀BM), and [6,6]-phenyl-C₇₁-butyric acid methyl ester (PC₇₁BM).

In some embodiments, the electron-donating polymer is of formula (III):

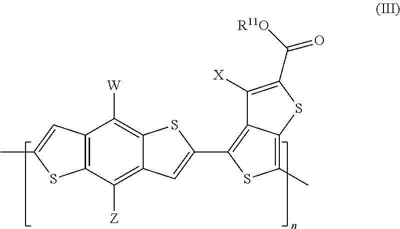

wherein W and Z are independently selected from the group consisting of hydrogen, unsubstituted or substituted alkyl, unsubstituted or substituted alkoxyl, unsubstituted or substituted cycloalkyl, unsubstituted or substituted heterocycloalkyl, unsubstituted or substituted aryl, unsubstituted or substituted aryloxyl, and unsubstituted or substituted heteroaryl; R¹¹ is selected from the group consisting of hydrogen, unsubstituted or substituted alkyl, unsubstituted or substituted cycloalkyl, unsubstituted or substituted heterocycloalkyl, unsubstituted or substituted aryl, and unsubstituted or substituted heteroaryl; X is selected from the group consisting of F, Cl and Br; and n is an integer greater than 0.

In some embodiments, formula (III) is further characterized as formula (IIIa):

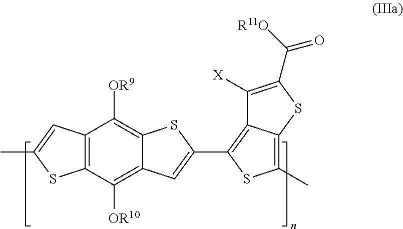

wherein R⁹, R¹⁰, and R¹¹ are independently selected from the group consisting of hydrogen, unsubstituted or substituted alkyl, and unsubstituted or substituted aryl; and X is selected from the group consisting of F and Cl.

In some embodiments, R⁹, R¹⁰, and R¹¹ are independently C₁₋₃₀ alkyl. In some embodiments, R⁹, R¹⁰, and R¹¹ are independently 2-ethylhexyl. In some embodiments, W and Z are independently unsubstituted or substituted heteroaryl. In some embodiments, W and Z are independently substituted heteroaryl. In some embodiments, W and Z are independently substituted thienyl. In some embodiments, W and Z are independently thienyl substituted with C₁₋₃₀ alkyl. In some embodiments, W and Z are independently thienyl substituted with 2-ethylhexyl. In some embodiments, both of W and Z are substituted thienyl. In some embodiments, both of W and Z are thienyl substituted with C₁₋₃₀ alkyl. In some embodiments, both of W and Z are thienyl substituted with 2-ethylhexyl. In some embodiments, X is F. In some embodiments, X is Cl.

In some embodiments, formula (IIIa) is further characterized as having the formula:

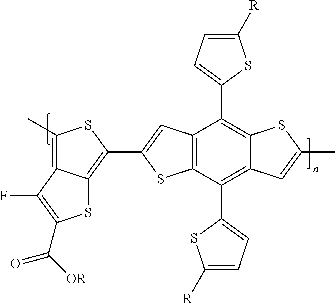

where each R is 2-ethylhexyl.

In some embodiments, the ratio of the polymer of formula (I) and the polymer of formula (III) to the electron-withdrawing material is in a range of about 1:0.5 to about 1:4. In some embodiments, the ratio of the polymer of formula (I) and the polymer of formula (III) to the electron-withdrawing material is in a range of about 1:1 to about 1:4. In some embodiments, the ratio of the polymer of formula (I) and the polymer of formula (III) to the electron-withdrawing material is about 1:1.5. In some embodiments, the ratio of the polymer of formula (III) to the polymer of formula (I) and to the electron-withdrawing material is about 0.9:0.1:1.5. In some embodiments, the ratio of the polymer of formula (III) to the polymer of formula (I) and to the electron-withdrawing material is about 0.8:0.2:1.5. In some embodiments, the ratio of the polymer of formula (III) to the polymer of formula (I) and to the electron-withdrawing material is about 0.7:0.3:1.5. In some embodiments, the ratio of the polymer of formula (III) to the polymer of formula (I) and to the electron-withdrawing material is about 0.5:0.5:1.5.

In one aspect, the aforementioned polymers and compositions are used in or are in the form of any one of a solar cell, an optical device, an electroluminescent device, a photovoltaic cell, semiconducting cell, or photodiode. In some embodiments, the use or form is a solar cell. In some embodiments, the use or form is an optical device. In some embodiments, the use or form is an electroluminescent device. In some embodiments, the use or form is a photovoltaic cell. In some embodiments, the use or form is a semiconducting cell. In some embodiments, the use or form is a photodiode.

### BRIEF DESCRIPTION OF THE DRAWINGS

In this disclosure, both of “PID2” and “PIB2” are used as the acronyms of poly-3-oxothieno[3,4-d]isothiazole 1,1-dioxide/benzodithiophene.

FIGS. 1A and 1B show normalized UV-vis absorption spectra of the polymers PID1, PID2, PPB1 and PPB2. a) in diluted chloroform solution and b) in pristine polymer films in some embodiments.

FIGS. 2A, 2B, 2C, and 2D show cyclic voltammetry (CV) diagrams of some embodiments including PID1 (a), PID2 (b), PPB1 (c), and PPB2 (d).

FIGS. 3A and 3B show (a) characteristic J-V curves of some embodiments including four solar cells and (b) external quantum efficiency (EQE) curves of the four solar cells.

FIG. 4 shows hole mobility curves for some embodiments including PID1, PID2, PPB1 and PPB2 using spacing charge limited current (SCLC) method.

FIGS. 5A, 5B, 5C, 5D, 5E, and 5F show transmission electron microscopy (TEM) images of some embodiments including polymer/PC₇₁BM blend films prepared from chlorobenzene:1,8-diiodooctane (CB/DIO) (97/3, v/v) with PID1 (a), PID2 (b), PPB1 (c), PPB2 (d) and from chlorobenzene without 1,8-diiodooctane, PID1 (e), PID2 (f). (The scale bar is 200 nm).

FIG. 6 shows J-V curve of an embodiment, namely a PID1 device without 1,8-diiodooctane (DIO).

FIGS. 7A, 7B, and 7C show 2-dimensional and linecut of Grazing Incidence Wide Angle X-ray Scattering (GIWAXS) spectra of some embodiments including PID1 prepared from different conditions: a) neat polymer film, b) PID1-PC₇₁BM without 1,8-diiodooctane, and c) PID1-PC₇₁BM with 1,8-diiodooctane.

FIG. 8 shows correlation of power conversion efficiency (PCE) values with calculated dipolar changes of polymer repeating unit in some embodiments.

FIG. 9 shows the charge separation (rise) and recombination (decay) dynamics monitored at the signals of the cationic state in the PID1 polymer of some embodiments. For comparison, the charge separation and charge recombination of PTB7 are also shown.

FIGS. 10A, 10B, 10C, and 10D show composition properties and device structure of some embodiments: a. Chemical structures of PTB7, PID2, and PC₇₁BM. b. Energy levels of electrodes and active layer materials used in ternary blend solar cells. c. Device structure of solar cells in one embodiment. d. UV-vis absorption spectra of ternary PTB7:PID2:PC₇₁BM blend with different ratios of PTB7:PID2. The acronym “PIB2” in FIG. 10 corresponds to “PID2.”

FIGS. 11A, 11B, 11C, and 11D show various photovoltaic performance of some embodiments: a. Current-voltage characteristics of ternary solar cells with different polymer mixture ratios; b. external quantum efficiency (EQE) curves of ternary PTB7:PID2:PC₇₁BM blend different PID2 contents; c. Photocurrent density (Jₚₕ) versus effective voltage (V_{eff}) characteristics; d. Dependence of J_{sc} on light intensity of ternary system with different polymer ratios. The acronym “PIB2” in FIG. 11 corresponds to “PID2.”

FIGS. 12A, 12B, 12C, and 12D show transmission electron microscopy (TEM) images of some embodiments: a. PTB7:PC₇₁BM (1:1.5). b. PTB7:PID2:PC₇₁BM (0.9:0.1:1.5). c. PTB7:PID2:PC₇₁BM (0.7:0.3:1.5). d. PID2:PC₇₁BM (1:1.5).

FIGS. 13A, 13B, 13C, 13D, 13E, and 13F show two-dimensional Grazing Incidence Wide Angle X-ray Diffraction (2D GIWAX) patterns of some embodiments on PEDOT:PSS-modified Si substrates. a. PTB7:PC₇₁BM (1:1.5). b. PTB7:PID2:PC₇₁BM (0.9:0.1:1.5). c. PTB7:PID2:PC₇₁BM (0.7:0.3:1.5). d. PTB7:PID2:PC₇₁BM (0.5:0.5:1.5). e. PTB7:PID2:PC₇₁BM (0.3:0.7:1.5). f. PID2:PC₇₁BM (1:1.5). The acronym “PIB2” in FIG. 13 corresponds to “PID2.”

FIG. 14 shows resonant soft x-ray scattering (RSoXS) profiles of some embodiments. The acronym “PIB2” in FIG. 14 corresponds to “PID2.”

FIG. 15 shows photocurrent density (Jₚₕ) versus effective voltage (V_{eff}) characteristics for some embodiments with various ratios of PTB7 and PID2.

FIG. 16 shows hole mobility for PTB7:PID2 at various ratios. The acronym “PIB2” in FIG. 16 corresponds to “PID2.”

FIGS. 17A, 17B, 17C, 17D, 17E, 17F, and 17G show atomic force microscopy (AFM) images of PTB7:PC₇₁BM (1:1.5) (a), PTB7:PID2:PC₇₁BM (0.9:0.1:1.5) (b), PTB7:PID2:PC₇₁BM (0.7:0.3:1.5) (c), PTB7:PID2:PC₇₁BM (0.5:0.5:1.5) (d), PTB7:PID2:PC₇₁BM (0.3:0.7:1.5) (e), PTB7:PID2:PC₇₁BM (0.1:0.9:1.5) (f), and PID2:PC₇₁BM (1:1.5) (g).

FIGS. 18A, 18B, 18C, and 18D show composition properties of some embodiments: a. Chemical structures of PTB7-Th, PID2, and PC₇₁BM. b. Energy levels of electrodes and active layer materials used in ternary blend solar cells. c. Current-voltage characteristics of ternary solar cells with different polymer mixture ratios with 0%, 10%, and 20% PID2 content. d. UV-vis absorption spectra of ternary PTB7-Th:PID2:PC₇₁BM blend with different ratios of PTB7-Th:PID2.

### DETAILED DESCRIPTION

Unless defined otherwise, all technical and scientific terms used herein have the same meaning as commonly understood to one of ordinary skill in the art to which this invention belongs. When describing the compounds, compositions, methods and processes of this invention, the following terms have the following meanings, unless otherwise indicated.

### DEFINITIONS

“Alkyl” by itself or as part of another substituent refers to a hydrocarbon group which may be linear, cyclic, or branched or a combination thereof having the number of carbon atoms designated (i.e., C₁₋₃₀ means one to thirty carbon atoms). Examples of alkyl groups include methyl, ethyl, n-propyl, isopropyl, n-butyl, t-butyl, isobutyl, sec-butyl, 2-ethylhexyl, cyclohexyl, cyclopentyl, (cyclohexyl)methyl, cyclopropylmethyl, bicyclo[2.2.1]heptane, bicyclo[2.2.2]octane, etc. Alkyl groups can be substituted or unsubstituted, unless otherwise indicated. Examples of substituted alkyl include haloalkyl, polyhaloalkyl, such as polyfluoroalkyl and polychloroalkyl, aminoalkyl, aralkyl and the like. Aralkyl refers to aryl-substituted alkyl, for example, benzyl and phenylethyl. Alkyl groups also include straight-chained and branched alkyl “Alkoxy” refers to —O-alkyl. Examples of an alkoxy group include methoxy, ethoxy, n-propoxy, etc.

The term “cycloalkyl,” as used herein, refers to a group derived from a monocyclic, saturated carbocycle, having three to eight (for example three to six) carbon atoms, by removal of a hydrogen atom from the saturated carbocycle. Representative examples of cycloalkyl groups include, but are not limited to, cyclopropyl, cyclopentyl, and cyclohexyl. When a cycloalkyl group contains one or more double bond(s) in the ring, yet not aromatic, it forms a “cycloalkenyl” group.

The term “heterocycloalkyl,” as used herein, refers to a 3- to 10-membered monocyclic or bicyclic nonaromatic group comprising one or more (for example one to three) heteroatoms independently selected from nitrogen, oxygen, and sulfur in the nonaromatic ring(s). The heterocyclyl groups of the present disclosure can be attached to the parent molecular moiety through a carbon atom or a nitrogen atom in the group. A heterocylcyl group can be saturated or unsaturated, for example, containing one or more double bond(s) in the ring. Examples of heterocyclyl groups include, but are not limited to, morpholinyl, oxazolidinyl, piperazinyl, piperidinyl, pyrrolidinyl, tetrahydrofuryl, thiomorpholinyl, and indolinyl, or the like.

“Aryl” refers to a polyunsaturated, aromatic hydrocarbon group having a single ring (monocyclic) or multiple rings (bicyclic), which can be fused together or linked covalently. Aryl groups with 6-10 carbon atoms are preferred, where this number of carbon atoms can be designated by C₆₋₁₀, for example. Examples of aryl groups include phenyl and naphthalene-1-yl, naphthalene-2-yl, biphenyl and the like. Aryl groups can be substituted or unsubstituted, unless otherwise indicated. “Aryloxy” refers to —O-aryl.

The term “amino” refers to —NRR′, where R and R′ are independently selected from hydrogen, alkyl, aryl, aralkyl, and alicyclic, all except hydrogen are optionally substituted. In some embodiments, R and R′ can form a cyclic ring together with the nitrogen atom of —NRR′. The ring system may be from 5-7 members and may be optionally fused with another ring group including cycloalkyl, aryl, and heteroaryl.

The term “halogen,” by itself or as part of a substituent refers to a chlorine, bromine, iodine, or fluorine atom.

The term “heteroaryl,” as used herein, refers to a mono-, bi-, or tri-cyclic aromatic radical or ring having from five to ten ring atoms of which at least one ring atom is selected from S, Se, O, and N; zero, one or two ring atoms are additional heteroatoms independently selected from S, Se, O, and N; and the remaining ring atoms are carbon, wherein any N or S contained within the ring may be optionally oxidized. Heteroaryl includes, but is not limited to, pyridinyl, pyrazinyl, pyrimidinyl, pyrrolyl, pyrazolyl, imidazolyl, thiazolyl, oxazolyl, isooxazolyl, thiadiazolyl, oxadiazolyl, thienyl, furanyl, quinolinyl, isoquinolinyl, benzimidazolyl, benzooxazolyl, quinoxalinyl, and the like. The heteroaromatic ring may be bonded to the chemical structure through a carbon or heteroatom, for example “heteroaryloxy” refers to the group —O-heteroaryl in which the heteroaryl ring is bonded to a chemical structure through an exocyclic oxygen.

“Heteroatom” is meant to include oxygen (O), nitrogen (N), sulfur (S), selenium (Se) and silicon (Si).

“Haloalkyl” as a substituted alkyl group refers to a monohaloalkyl or polyhaloakyl group, most typically substituted with from 1-3 halogen atoms. Examples include 1-chloroethyl, 3-bromopropyl, trifluoromethyl and the like.

Polymers

Calculations of dipolar change based on the polymer repeating units led to two polymer systems, both copolymers containing benzodithiophene (BDT). One is based on thieno[3,4-c]pyrrole-4,6-dione (TPD) and the other on 3-oxothieno[3,4-d]isothiazole 1,1-dioxide (TID). The TPD unit has recently been incorporated into various low band gap conjugated polymer systems. Previously explored as an artificial sweetener, TID unit bears both a sulfonyl and a carbonyl group, and is more electron deficient than TPD. The calculation results showed that the repeating units of polymers containing TPD and TID respectively, i.e. polythieno[3,4-c]pyrrole-4,6-dione benzodithiophene (PPB) and poly-3-oxothieno[3,4-d]isothiazole 1,1-dioxide/benzodithiophene (PID) exhibit a larger Δμ_{ge} than polymer polythieno[3,4-b]-thiophene/benzodithiophene (PTB7). Thus, two polymers, PPB and PID, were synthesized and characterized under identical conditions to investigate the effect of further increasing Δμ_{ge} on solar cell performance. The results showed a clear decrease in device PCE as the Δμ_{ge} increased further, indicating that an optimized Δμ_{ge} value of around 4.0 Debye is needed to achieve a high PCE for organic photovoltaic (OPV) devices.

In one aspect, a polymer is of formula (I):

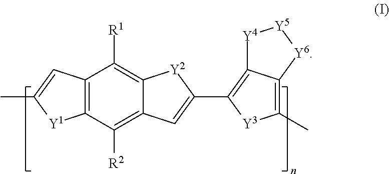

Y¹, Y², Y³, Y⁴, Y⁵, and Y⁶ are independently selected from the group consisting of O, S, Se, NR³, S(O), S(O)₂, CR⁴R⁵ and C(O). R¹, R², R³, R⁴ and R⁵ are independently selected from the group consisting of hydrogen, halogen, unsubstituted or substituted alkyl, unsubstituted or substituted alkoxy, unsubstituted or substituted aryl, unsubstituted or substituted aryloxy, unsubstituted or substituted heteroaryl, and unsubstituted or substituted heteroaryloxy. The value of n is an integer greater than 0.

In some embodiments, R¹ and R² are independently alkoxy. In some embodiments, R¹ and R² are independently C₁₋₃₀ alkoxy. In some embodiments, R¹ and R² are independently 2-ethylhexyloxy. In some embodiments, both R¹ and R² are 2-ethylhexyloxy.

In some embodiments, Y¹, Y², and Y³ are independently S. In some embodiments, Y¹, Y², and Y³ are S.

In some embodiments, Y⁴ is S(O)₂.

In some embodiments, Y⁵ is NR³. In some embodiments, R³ is C₁₋₃₀ alkyl. In some embodiments, R³ is 2-ethylhexyl. In some embodiments, R³ is octyl.

In some embodiments, Y⁶ is C(O).

In some embodiments, n is less than 200.

In some embodiments, a polymer is of formula (II):

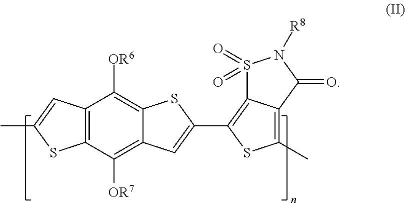

where R⁶, R⁷, and R⁸ are independently selected from the group consisting of hydrogen, unsubstituted or substituted alkyl, and unsubstituted or substituted aryl. The value of n is an integer greater than 0.

In some embodiments, R⁶, R⁷, and R⁸ are independently alkyl. In some embodiments, R⁶, R⁷, and R⁸ are independently C₁₋₃₀ alkyl. In some embodiments, R⁶, R⁷, and R⁸ are independently 2-ethylhexyl. In some embodiments, R⁶, R⁷, and R⁸ are all 2-ethylhexyl. In some embodiments, R⁸ is octyl.

Compositions

In one aspect, a composition comprises an electron-withdrawing material, a first electron-donating polymer, and a second electron-donating polymer. In some embodiments, the first-electron donating polymer is of formula (I):

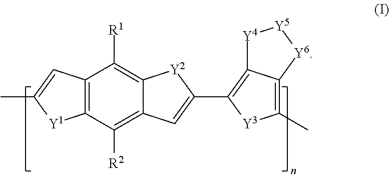

Y¹, Y², Y³, Y⁴, Y⁵, and Y⁶ are independently selected from the group consisting of O, S, Se, NR³, S(O), S(O)₂, CR⁴R⁵ and C(O). R¹, R², R³, R⁴ and R⁵ are independently selected from the group consisting of hydrogen, halogen, unsubstituted or substituted alkyl, unsubstituted or substituted alkoxy, unsubstituted or substituted aryl, unsubstituted or substituted aryloxy, unsubstituted or substituted heteroaryl, and unsubstituted or substituted heteroaryloxy. The value of n is an integer greater than 0.

In some embodiments, R¹ and R² are independently alkoxy. In some embodiments, R¹ and R² are independently C₁₋₃₀ alkoxy. In some embodiments, R¹ and R² are independently 2-ethylhexyloxy. In some embodiments, both R¹ and R² are 2-ethylhexyloxy.

In some embodiments, Y¹, Y², and Y³ are independently S. In some embodiments, Y¹, Y², and Y³ are S.

In some embodiments, Y⁴ is S(O)₂.

In some embodiments, Y⁵ is NR³. In some embodiments, R³ is C₁₋₃₀ alkyl. In some embodiments, R³ is 2-ethylhexyl. In some embodiments, R³ is octyl.

In some embodiments, Y⁶ is C(O).

In some embodiments, n is less than 200.

In some embodiments, the first-electron donating polymer is of formula (II):

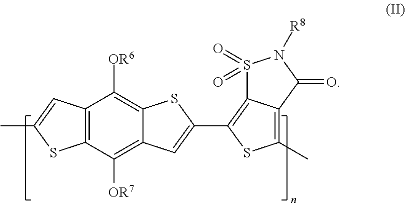

R⁶, R⁷, and R⁸ are independently selected from the group consisting of hydrogen, unsubstituted or substituted alkyl, and unsubstituted or substituted aryl. The value of n is an integer greater than 0.

In some embodiments, R⁶, R⁷, and R⁸ are independently alkyl. In some embodiments, R⁶, R⁷, and R⁸ are independently C₁₋₃₀ alkyl. In some embodiments, R⁶, R⁷, and R⁸ are independently 2-ethylhexyl. In some embodiments, R⁶, R⁷, and R⁸ are 2-ethylhexyl. In some embodiments, R⁸ is octyl.

In some embodiments, the value of n is less than 200.

In some embodiments, the electron-withdrawing material is a fullerene derivative. In some embodiments, the fullerene derivative contains 60 to 90 carbon atoms (i.e. C₆₀ to C₉₀ derivatives). In some embodiments, the electron-withdrawing fullerene derivative is selected from the group consisting of C₆₁, C₇₀, C₇₁, C₈₁, and C₉₁ derivatives. In some embodiments, the electron-withdrawing fullerene derivative is selected from the group consisting of [6,6]-phenyl-C₆₁-butyric acid methyl ester (PC₆₁BM), [6,6]-phenyl-C₇₀-butyric acid methyl ester (PC₇₀BM) and [6,6]-phenyl-C₇₁-butyric acid methyl ester (PC₇₁BM).

In some embodiments, the second electron-donating polymer is of formula (III):

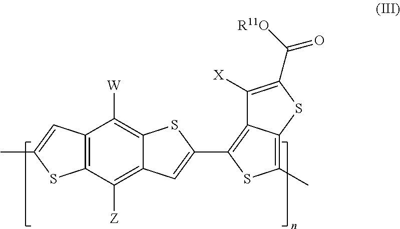

where W and Z are independently selected from the group consisting of hydrogen, unsubstituted or substituted alkyl, unsubstituted or substituted alkoxyl, unsubstituted or substituted cycloalkyl, unsubstituted or substituted heterocycloalkyl, unsubstituted or substituted aryl, unsubstituted or substituted aryloxyl, and unsubstituted or substituted heteroaryl. R¹¹ is selected from the group consisting of hydrogen, unsubstituted or substituted alkyl, unsubstituted or substituted cycloalkyl, unsubstituted or substituted heterocycloalkyl, unsubstituted or substituted aryl, and unsubstituted or substituted heteroaryl. X is selected from the group consisting of F, Cl, and Br. The value of n is an integer greater than 0.

In some embodiments, W and Z are independently unsubstituted or substituted heteroaryl. In some embodiments, W and Z are independently substituted heteroaryl. In some embodiments, W and Z are independently substituted thienyl. In some embodiments, W and Z are independently thienyl substituted with C₁₋₃₀ alkyl. In some embodiments, W and Z are independently thienyl substituted with 2-ethylhexyl. In some embodiments, both of W and Z are substituted thienyl. In some embodiments, both of W and Z are thienyl substituted with C₁₋₃₀ alkyl. In some embodiments, both of W and Z are thienyl substituted with 2-ethylhexyl.

In some embodiments, X is F. In some embodiments, X is Cl. In some embodiments, X is Br.

In some embodiments, the second electron-donating polymer is of formula (IIIa):

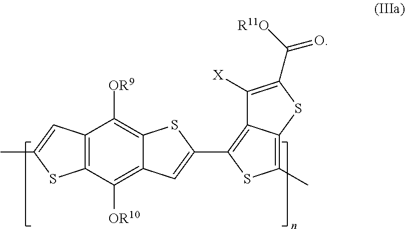

where R⁹, R¹⁰, and R¹¹ are independently selected from the group consisting of hydrogen, unsubstituted or substituted alkyl, and unsubstituted or substituted aryl.

In some embodiments, R⁹, R¹⁰, and R¹¹ are independently alkyl. In some embodiments, R⁹, R¹⁰, and R¹¹ are independently C₁₋₃₀ alkyl. In some embodiments, R⁹, R¹⁰, and R¹¹ are independently 2-ethylhexyl. In some embodiments, R⁹, R¹⁰, and R¹¹ are 2-ethylhexyl. In some embodiments, X is F. In some embodiment, X is Cl. In some embodiments, X is Br.

In some embodiments, the second electron-donating polymer is PTB10 having the structure shown below:

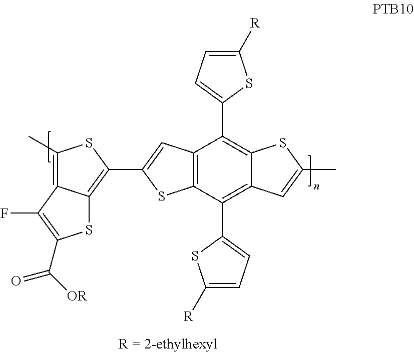

In some embodiments, the ratio of the first and second electron-donating polymers to the electron-withdrawing material is in a range of about 1:0.5 to about 1:4. In some embodiments, the ratio of the first and second electron-donating polymers to the electron-withdrawing material is in a range of about 1:1 to about 1:2. In some embodiments, the ratio of the first and second electron-donating polymers to the electron-withdrawing material is about 1:1.5. In some embodiments, the ratio of the first and second electron-donating polymers to the electron-withdrawing fullerene derivative is in a range of about 1:0.5 to about 1:4. In some embodiments, the ratio of the first and second electron-donating polymers to the electron-withdrawing fullerene derivative is in a range of about 1:1 to about 1:2. In some embodiments, the ratio of the first and second electron-donating polymers to the electron-withdrawing fullerene derivative is about 1:1.5.

In some embodiments, the composition comprises the polymer of formula (I) and the polymer of formula (III). In some embodiments, the ratio of the polymer of formula (III) to the polymer of formula (I) and to the electron-withdrawing fullerene derivative is about 0.9:0.1:1.5. In some embodiments, the ratio of the polymer of formula (III) to the polymer of formula (I) and to the electron-withdrawing fullerene derivative is about 0.8:0.2:1.5. In some embodiments, the ratio of the polymer of formula (III) to the polymer of formula (I) and to the electron-withdrawing fullerene derivative is about 0.7:0.3:1.5. In some embodiments, the ratio of the polymer of formula (III) to the polymer of formula (I) and to the electron-withdrawing fullerene derivative is about 0.5:0.5:1.5. In some embodiments, the ratio of the polymer of formula (III) to the polymer of formula (I) and to the electron-withdrawing fullerene derivative is about 0.3:0.7:1.5. In some embodiments, the ratio of the polymer of formula (III) to the polymer of formula (I) and to the electron-withdrawing fullerene derivative is about 0.1:0.9:1.5.

### Examples

### 1. Synthesis of Polymers

The N-alkyl, 3-oxothieno[3,4-d]isothiazole 1,1-dioxide (TID) unit was prepared according to a modified literature procedure. In order to anchor alkyl side chains on the original artificial sweetener unit, the phase transfer catalyst 15-crown-5 was used to achieve a relatively high conversion yield. Two different solublizing alkyl side chains were used, octyl and 2-ethylhexyl (used in poly-3-oxothieno[3,4-d]isothiazole 1,1-dioxide/benzodithiophene PID1 and PID2, respectively). The final monomer N-alkyl, 3-oxothieno[3,4-d]isothiazole 1,1-dioxide was prepared via a modified bromination procedure in the presence of strong Bronsted acids (see Scheme 1 for synthetic details).

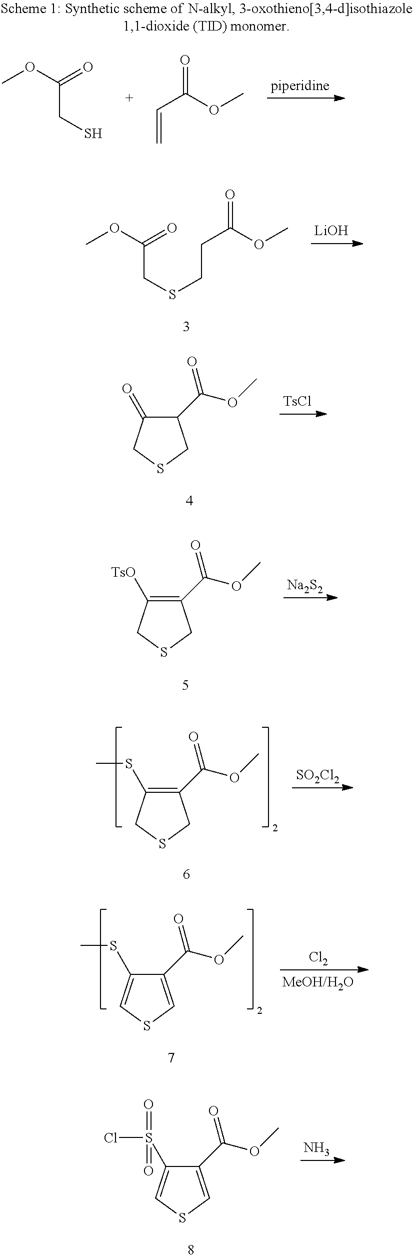

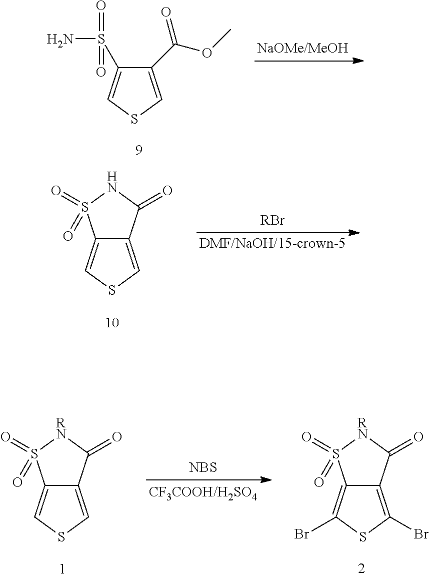

The benzodithiophene (BDT) unit was synthesized according to known procedures. Polymers were synthesized via Stille polycondensation using Pd₂(dba)₃/P(o-tolyl)₃ catalyst in refluxing chlorobenzene (CB) for 48 hours (Scheme 2).

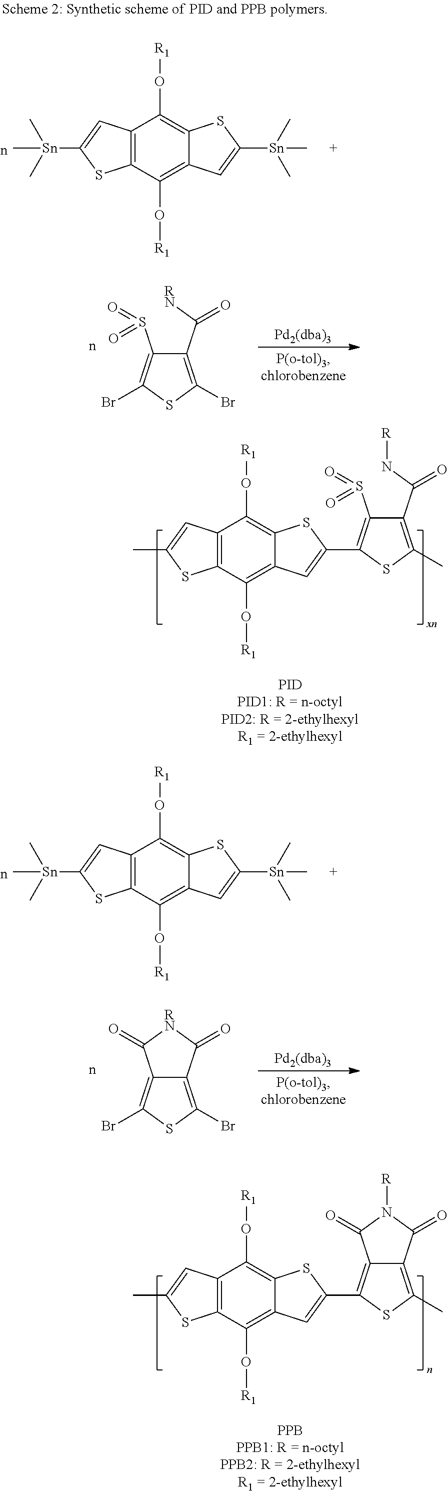

Unless otherwise stated, all chemicals obtained from commercial suppliers were used without further purification. All solvents were purified with a standard distillation procedure prior to use. All reactions were carried out under argon atmosphere. Nuclear magnetic resonance spectra were obtained in deuterated chloroform (CDCl₃) with TMS as internal reference; chemical shifts (δ) are reported in parts per million. Column chromatography was carried out on silica gel (silica 60M, 400-230 mesh). TLC analyses were performed on commercial flexible polyester backing plates bearing a 0.25 mm layer thickness. ¹H NMR spectra were recorded at 400 or 500 MHz on Bruker DRX-400 or DRX 500 spectrometers, respectively.

Molecular weights (MW) and MW distributions of polymers were determined by using GPC with a Waters Associates liquid chromatograph equipped with a Waters 510 HPLC pump, a Waters 410 differential refractometer and a Waters 486 tunable absorbance detector. Polystyrene was used as the standard and THF as the eluent.

α,β-Dicarbomethoxymethylethyl sulfide (3) Methyl acrylate (90 mL, 989 mmol) was added dropwise to the ice-cooled mixture of methyl thioglycolate (84 mL, 942 mmol) and 2 mL of piperidine during a period of 1 hour. Additional 1 mL of peperidine was added in the middle. Then the reaction was warmed to 50° C. and maintained stirring overnight. A yellow solution was obtained. The reaction was then washed by water and dried over sodium sulfate. The product was purified through vacuum distillation to give a colorless liquid (177.4 g, 98%)¹H NMR (500 MHz, CDCl₃) δ 3.75 (s, 3H), 3.71 (s, 3H), 3.26 (s, 2H), 2.92 (t, 2H), 2.66 (t, 2H).

Methyl tetrahydro-4-oxothiophene-3-carboxylate (4) Lithium methoxide (12.3 g, 294.3 mmol) was weighted into a three necked flask and dissolved in methanol and toluene mixture. Compound 3 (56.6 g, 294.3 mmol) was added dropwise at 70° C. The reaction was then raised up to 110° C. and stirred overnight. A lot of pale yellow precipitate was generated after removal of methanol. The solid was then suspended in CH₂Cl₂/H₂O system and acidified with acetic acid. Organic phase was collected and dried with sodium sulfate. Pale brown crystals were obtained as the product (25.3 g, 53.7%). ¹H NMR (500 MHz, CDCl₃): δ 3.83 (t, 2H), 3.80 (s, 3H), 3.79 (s, 1H), 3.77 (t, 2H).

Methyl 2, 5-Dihydro-4-(p-toluenesulfonato)thiophene-3-carboxylate (5) Compound 4 (25.3 g, 157.9 mmol) and N-methylmorpholine (24.3 mL, 221.1 mmol) were dissolved in dichloromethane and cooled by ice-water bath. The solution of p-toluene sulfonylchloride (31.6 g, 165.8 mmol) in dichloromethane was added dropwise over a period of 30 minutes. The mixture was then stirred for another 1 hour, and washed by water. The organic layer was separated, dried over sodium sulfate. The final product was collected a white solid (44.0 g, 88.5%) via recrystallization from methanol. ¹H NMR (500 MHz, CDCl₃): δ 7.88 (d, 2H), 7.38 (d, 2H), 3.97 (t, 2H), 3.83 (t, 2H), 3.62 (s, 3H), 2.47 (s, 3H).

Dimethyl 4, 4′-Dithiobis(2,5-dihydrothiophene-3-carboxylate) (6) The sodium disulfide solution was prepared by adding sulfur powder (2.7 g, 83.9 mmol) into the refluxing sodium sulfide (6.5 g, 83.9 mmol) solution in methanol. The mixture was maintained refluxing till sulfur was completely dissolved. The solution was then transferred to a dropping funnel and added dropwise to the ice-cooled solution of compound 5 (44.0 g, 139.8 mmol) in acetone over a period of 2 hours. The mixture was stirred for another 6 hours before poured into cold water. The precipitate was filtered and washed by water and methanol. Hot acetone and hexane were used to get rid of any tosylate and sulfur. A white solid was obtained in the end (17.9 g, 72.8%). ¹H NMR (500 MHz, CDCl₃): δ 4.19 (t, 4H), 4.07 (t, 4H), 3.79 (s, 6H).

Dimethyl 4,4′-Dithiobis(thiophene-3-carboxylate) (7) To the solution of compound 6 (17.9 g, 50.9 mmol) in dichloromethane was added sulfonyl chloride (9.4 mL, 107.9 mmol) dropwise. The mixture was stirred overnight before quenched by sodium bicarbonate solution. A clear greenish solution was obtained. The final product was purified through recrystallization from methanol to yield a yellow solid (16.1 g, 91.4%). ¹H NMR (500 MHz, CDCl₃): δ 8.18 (d, 2H), 7.25 (d, 2H), 3.90 (s, 3 H).

Methyl 4-(Chlorosulfonyl)thiophene-3-carboxylate (8) Compound 7 (4.0 g, 11.5 mmol) was grounded and suspended in a mixture of MeOH/H₂O and cooled to 0° C. Chlorine gas was introduced into the system during a period of 4 hrs until a clear solution was obtained. Methanol was removed under vacuum and the residue was washed by water and extracted by dichloromethane. The final product was collected as a solid (3.4 g, 61.3%). ¹H NMR (500 MHz, CDCl₃): δ 8.37 (d, 1H), 8.25 (d, 1H), 3.97 (s, 3H).

Methyl 4-Sulfamoylthiophene-3-carboxylate (9) Compound 8 (3.0 g, 12.4 mmol) was dissolved in dichloromethane and cooled to 0° C. Ammonia gas was introduced during a period of 4 hours. A lot of white precipitate came out. The final product was extracted by dichloromethane after washed with water. An orange solid was obtained (2.4 g, 86.3%). ¹H NMR (500 MHz, CDCl₃): δ 8.19 (d, 1H), 8.13 (d, 1H), 5.74 (s, 2H), 3.94 (s, 3H).

2,3-Dihydro-3-oxothieno[3,4-d]isothiazole 1,1-Dioxide (10) Sodium (0.4 g, 16.1 mmol) was sliced into pieces and put into methanol. Compound 9 (2.4 g, 10.7 mmol) was added and the mixture was refluxed for 24 hours. Methanol was then evaporated and the residue was acidified by concentrated hydrochloric acid. The product thiophenesaccharin was recrystallized from water to yield brown crystals (1.3 g, 64.5%).

2-Octyl-2,3-dihydro-3-oxothieno[3,4-d]isothiazole 1,1-Dioxide (1) Thiophenesaccharin (0.26 g, 1.4 mmol) was dissolved in DMF together with sodium hydroxide (0.1 g, 2.1 mmol). 15-Crown-5 (28 μL, 10%) was added as a phase transfer catalyst. The reaction was kept at 80° C. overnight. The final product was purified through a column with eluent of CH₂Cl₂/hexane 3:1 to give a white solid (0.3 g, 80%). ¹H NMR (500 MHz, CDCl₃): δ 8.03 (d, 1H), 7.92 (d, 1H), 3.70 (t, 2H), 1.84 (m, 2H), 1.40 (m, 8H), 0.89 (t, 3H). LC-MS: m/z=301.

2-Octyl-2,3-dibromo-3-oxothieno[3,4-d]isothiazole 1,1-Dioxide (2) Compound 1 (0.3 g, 1.1 mmol) was dissolved in 3.4 mL of concentrated sulfuric acid and 10 mL of trifluoroacetic acid. NBS (0.6 g, 3.4 mmol) was added in one portion and reaction mixture was stirred at 55° C. overnight. The brown solution was then poured into ice water and extracted with dichloromethane. Column chromatography was used to yield a white solid as the TID unit (0.33 g, 64%). ¹H NMR (500 MHz, CDCl₃): δ 3.67 (t, 2H), 1.81 (m, 2H), 1.35 (m, 8H), 0.89 (t, 3H). LC-MS: m/z=459.

Poly-3-oxothieno[3,4-d]isothiazole 1,1-dioxide/benzodithiophene (PID1). Compound 2 (2-Octyl-2,3-dibromo-3-oxothieno[3,4-d]isothiazole 1,1-dioxide) (223 mg, 0.49 mmol) was weighted into a 25 mL round bottom flask together with 2,6-bis(trimethyltin)-4,8-di(2-ethylhexyloxyl)benzo[1,2-b:4,5-b]dithiophene (374 mg, 0.49 mmol). Pd₂(dba)₃ (9 mg) was used as the catalyst with P(o-tolyl)₃ (12 mg) as the ligand. The flask was vacuumized and purged with argon in three successive cycles. Then anhydrous chlorobenzene (CB) was injected into the mixture via a syringe. The polymerization was performed at 120° C. for 48 hours under argon protection. A blue mixture was obtained and suction filtered through Celite to remove any palladium particles. The raw product was precipitated out in methanol and went through Soxhlet extraction by acetone, hexane and chloroform. The final polymers were again precipitated out in methanol and dried in vacuum, yielding PID1 (328 mg, 89.8%). ¹H NMR (500 MHz, CDCl₃): δ 8.60-9.00 (br, 1H), 7.60-8.10 (br, 1H), 4.10-4.55 (br, 4H), 3.60-4.00 (br, 2H), 0.90-2.20 (br, 45H). Calculated for C₃₉H₅₃NO₅S₄: C, 62.95; H, 7.18; S, 17.24. found: C, 63.62; H, 7.56; S, 17.48.

Polymers PID2 and PPB were synthesized through the same procedure as PID1 with respective monomers. They were all precipitated in methanol, collected by filtration followed by Soxhlet extraction using acetone, hexane, and finally chloroform. Polymers PTB7 and PTB10 were synthesized as the procedures provided in Y. Liang, D. Feng, Y. Wu, S.-T. Tsai, G. Li, C. Ray, L. Yu, J. Am. Chem. Soc. 2009, 131, 7792.

### 2. Optical and Electrical Properties of Polymers and Solar Cells

As shown by Gel Permeation Chromatography (GPC) measurements, these polymers exhibit number-averaged molecular weights between 12.0 and 18.6 kg/mol with a dispersity index (D) around 2 (Table 1). The structures of polymers were confirmed by 1H NMR spectra and elemental analyses (Table 2).

TABLE 1
Molecular Weight and Physical Properties of the Polymers.

| | Mn | | λₘₐₓ (nm) | | λₒₙₛₑₜ | E_{g}^{opt} | LUMO | HOMO |
|---|---|---|---|---|---|---|---|---|
| Polymer | (kDa) | [symbol] | Soln. | Film | (nm) | (eV) | (eV) | (eV) |
| PID1 | 12.0 | 2.9 | 597.5 | 605.5 | 686.4 | 1.81 | −3.55 | −5.44 |
| PID2 | 12.3 | 2.6 | 602 | 606.5 | 672.0 | 1.85 | −3.50 | −5.52 |
| PPB1 | 18.6 | 2.0 | 624.5 | 618.5, | 674.6 | 1.84 | −3.55 | −5.38 |
| | | | | 553 | | | | |
| PPB2 | 13.3 | 2.1 | 609 | 611.5, | 675.7 | 1.84 | −3.55 | −5.40 |
| | | | | 555 | | | | |

TABLE 2
Summary of Elemental Analysis Data.

| | % C | | % H | | % S | |
|---|---|---|---|---|---|---|
| Polymer | Theoretical | Calculated | Theoretical | Calculated | Theoretical | Calculated |
| PID1 | 63.81 | 63.62 | 7.39 | 7.56 | 16.60 | 17.48 |
| PID2 | 62.99 | 63.43 | 6.59 | 7.64 | 17.23 | 17.24 |
| PPB1 | 68.57 | 65.63 | 7.76 | 7.23 | 13.06 | 13.54 |
| PPB2 | 67.89 | 64.75 | 7.50 | 7.96 | 13.58 | 14.13 |

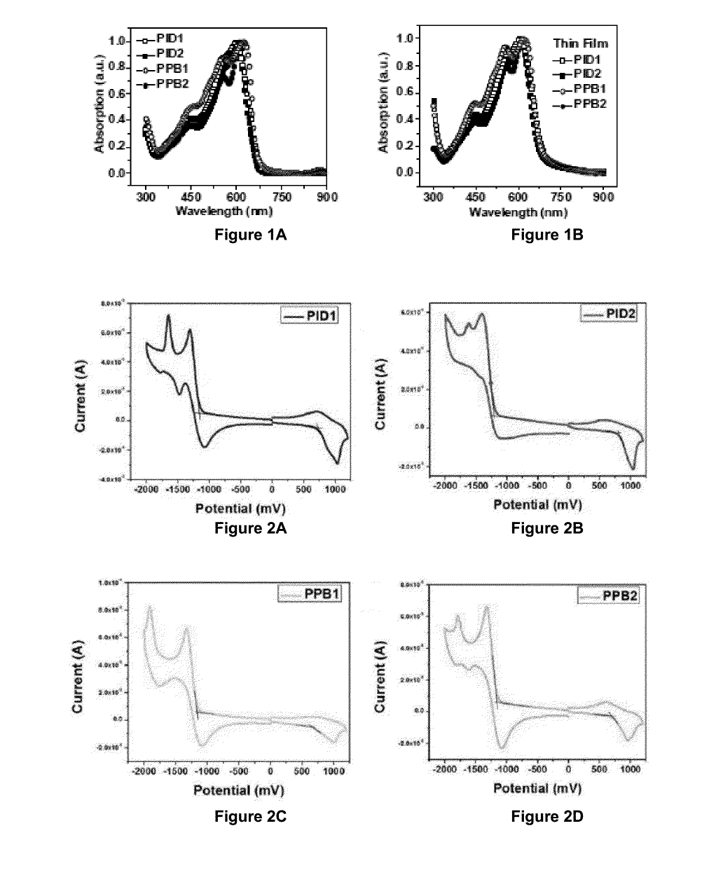

Both the solution and thin-film optical absorption spectra of the polymers are presented in FIGS. 1A-1B. All polymers showed similar absorption range from 320 to 700 nm, and the absorption edge was nearly identical. The absorption maximum of the PID polymers was slightly blue-shifted compared to the PPB polymers. The cyclic voltammetry (CV) (FIGS. 2A-2D) studies indicated that the HOMO energy levels of PID1 and PID2 were at −5.44 and −5.52 eV, approximately 0.1 eV lower than their corresponding PPBs; while the LUMO energy levels were at −3.55 eV and −3.50 eV, respectively.

2.1. Current-Voltage (J-V) Characteristics of the Polymer Solar Cells

Device Fabrication: The polymers and PC70BM were stirred at 80° C. for 12 hours under N₂ atmosphere in chlorobenzene and 1, 8-diodooctane (97:3, v/v). The polymer concentration was 10 mg/mL. ITO glass substrate was cleaned in water, acetone and isopropyl alcohol under sonication. After that, ITO glasses were exposed to ultraviolet ozone irradiation for 60 minutes. 30 nm of PEDOT:PSS was spin-coated at 6000 rpm for 1 minute onto ITO glasses and dried at 80° C. for 30 minutes. Active layers were spin coated using the as-prepared solutions in a glove box. 20 nm Ca and 80 nm Al cathodes were thermal evaporated in a glove box at a chamber pressure of ˜1.0×10⁻⁶ torr. The area of the solar cell is 3.14 mm².

Characterization: J-V characteristics of solar cells were measured under 1-sun, AM 1.5G irradiation (100 mW/cm²) from a solar simulator with a Xe lamp. The EQE measurement system was composed of a 250 W QTH lamp as the light source, a filter wheel, a chopper, a monochromator, a lock-in amplifier and a calibrated silicon photodetector. Optical properties were measured by using a Shimadzu UV-2401 PC UV-Vis spectrophotometer. Electrochemical studies were carried out by using Cyclic voltammetry (CV) with Ag/AgCI as the reference electrode while the redox potential of ferrocene/ferrocenium (Fc/Fc⁺) was measured under the same conditions for calibration.

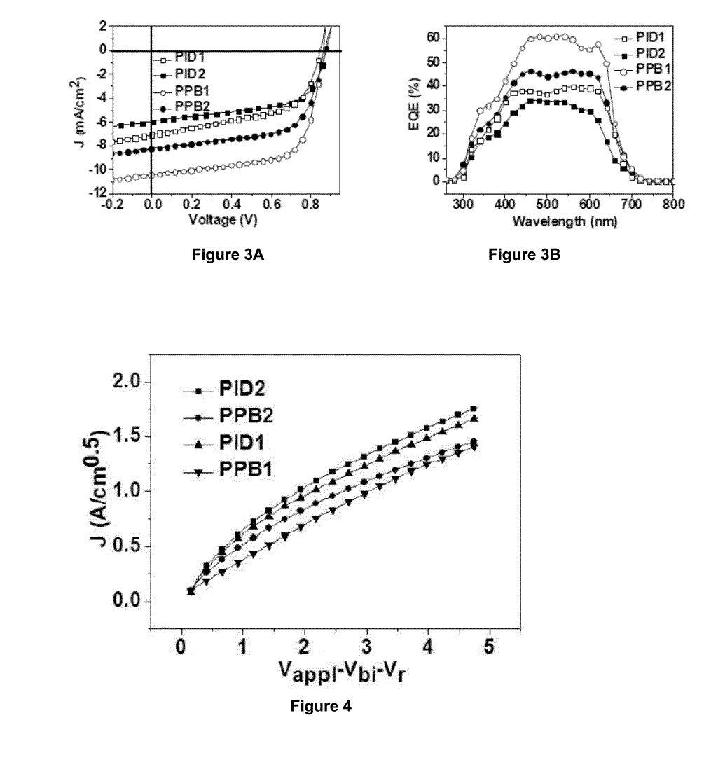

The photovoltaic properties were investigated in the device structure ITO/PEDOT:PSS/polymer[6,6]-phenyl-C71-butyric acid methyl ester (PC71BM)/Ca/Al. In this section, solar cell data used in comparison of physical properties were determined based on this device structure. The active layers of ˜100 nm were spin-coated from 10 mg/mL chlorobenzene (CB) and 1,8-diiodooctane (DIO) (v/v, 97:3) solutions. The corresponding J-V curves of the four polymer solar cells under AM 1.5G condition at 100 mW/cm² are presented in FIG. 3A. Representative characteristics of solar cells are summarized in Table 3. Devices fabricated from PID1, PID2, PPB1 and PPB2 showed best power conversion efficiency (PCE) values at 3.28%, 3.05%, 5.97%, and 4.48%, respectively. FIG. 3B depicts the external quantum efficiency (EQE) curves of the four solar cells. The PPB1 showed highest EQE values around 60% within the spectral range from 450 to 650 nm while PID2 showed the lowest EQE values ca 30%. Changes in EQE curves are in good agreement with the observed J_{sc} values from the four polymers. Hole mobility of all four polymers, measured using spacing charge limited current (SCLC) method, were ˜2.42×10⁻⁴, 2.71×10⁻⁴, 3.69×10⁻⁴ and 3.34×10⁻⁴ cm² V⁻¹ s⁻¹ for PID1, PID2, PPB1 and PPB2, respectively (FIG. 4). Along with the EQE curves, the mobility values match with the J_{sc} trend well. Although PIDs exhibits high open circuit voltage due to a low HOMO energy level, small current density and low fill factor limit the overall solar cell performance.

TABLE 3
Comparison of Photovoltaic Parameters of TID and TPD-containing
Polymers in the Blend with PC₇₁BM (CB/DIO,
Polymer/PCBM = 1:1.5 Weight ratio).

| | HOMO* | LUMO* | V_{oc} | | FF | |
|---|---|---|---|---|---|---|
| Polymer | (eV) | (eV) | (V) | J_{sc} (mA/cm²) | (%) | PCE (%) |
| PID1 | −5.44 | −3.55 | 0.85 | 7.06 | 54.7 | 3.28 |
| PID2 | −5.52 | −3.40 | 0.88 | 5.94 | 58.6 | 3.05 |
| PPB1 | −5.38 | −3.55 | 0.86 | 10.40 | 66.6 | 5.97 |
| PPB2 | −5.40 | −3.55 | 0.88 | 8.23 | 62.2 | 4.48 |

Note:
*From cyclic voltammetry data.

2.2. Morphology of Polymer Films

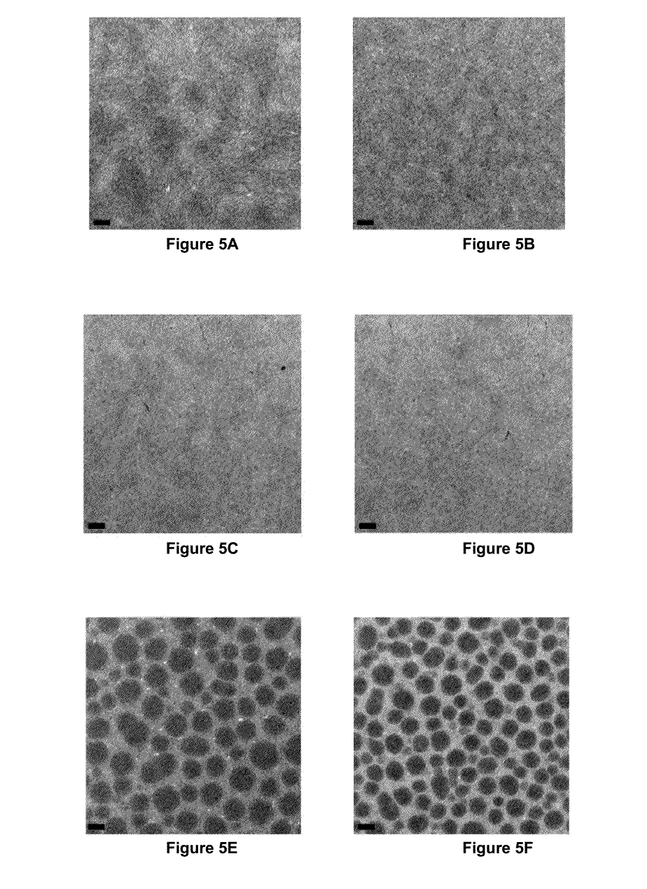

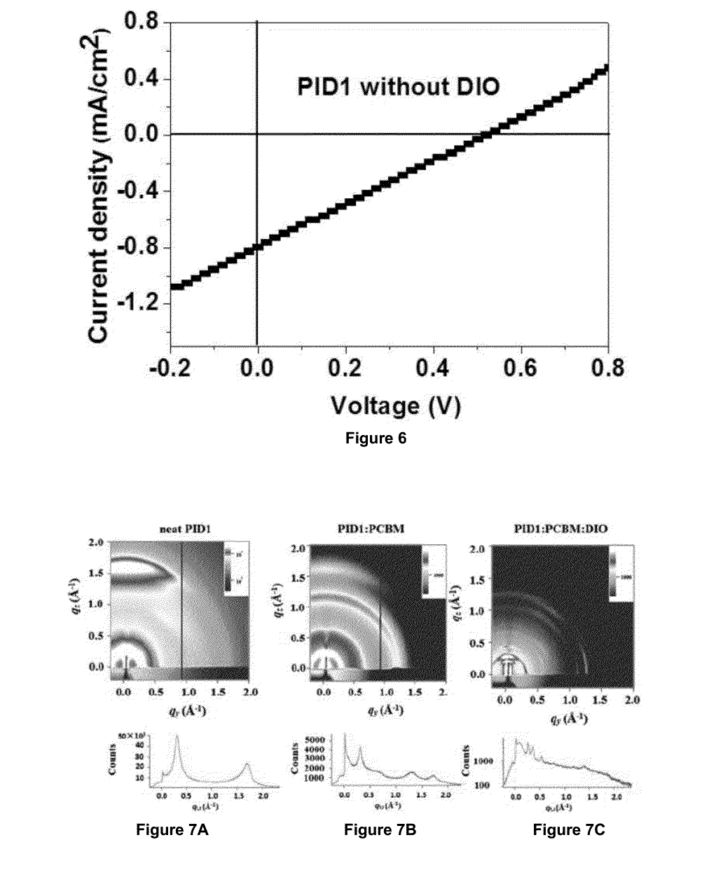

To ensure that the comparison of solar cell performance is meaningful, the morphologies of these polymer films were optimized for the device performance by using organic additive in the film fabrication. As shown in the transmission electron microscopy (TEM) images of blend films with and without 1,8-diiodooctane (DIO) in FIGS. 5A-5F, all four solar cells with DIO exhibit fine phase separations while severe phase segregation was observed in the blend films without DIO, leading to almost zero photovoltaic effect (FIG. 6).

2.3 GIWAX Measurement

Grazing incidence wide-angle X-ray scattering (GIWAXS) measurements were performed at the 8ID-E beamline at the Advanced Photon Source (APS), Argonne National Laboratory using x-rays with a wavelength of A=1.6868 Å and a beam size of ˜50 μm. The samples for the measurements were prepared on PEDOT:PSS modified Si substrates under the same conditions as those used for fabrication of solar cell devices.

An observation is that although the sulfonyl group adopts tetrahedron geometry with two oxygen atoms pointing out of the polymeric conjugation plane, the corresponding polymers exhibit enhanced backbone interactions, evidenced by the high crystallinity as clearly shown by GIWAXS results. The GIWAXS spectra showed a narrow peak width in the PID1 film, indicating a higher coherence length (3.5 nm) than that of the PPB1 (1.7 nm). Accompanying this is a strong scattering peak (010) with a d-spacing of 3.4 Å for pure polymer thin film of PID1, (FIGS. 7A-7C), shorter than its corresponding PPB1 polymer (Table 4). However, this strong interaction does not lead to higher mobility than PPB1, which is consistent with the possible role of trapping center to be discussed below.

TABLE 4
Summary of GIWAXS Data for Two Polymers PID and PPB.

| | | | | Additional π-π |
|---|---|---|---|---|
| Pure Polymer | q_{z} (Å⁻¹) | π-π stacking (Å) | q′_{z} (Å⁻¹) | stacking (Å) |
| PID1 | 1.86 | 3.4 | 1.72 | 3.7 |
| PID2 | 1.64 | 3.8 | | |
| PPB1 | 1.84 | 3.4 | | |
| PPB2 | 1.71 | 3.7 | | |

Without being bound by theory, it can be assumed that the smaller π-π stacking spacing is caused when the backbone is shifted parallel so that the tetrahedron sulfonyl groups can slip into each other. The π-π stacking peaks are more prominent in the out-plane direction, which implies that the polymer chains tend to adopt a parallel orientation to the substrate. When it was blended with PC71 BM in the absence of additive, the strong interaction still exists although the signal was weakened. Along with severe phase segregation observed in the transmission electron microscopy (TEM) images, this explained why no photovoltaic effect was observed. After the addition of 1,8-diiodooctane (DIO) to the composite, the π-packing is partially disrupted, however, the morphology is optimized by intercalation and the photovoltaic effect is enhanced.

2.4 Correlation of Δμ_{ge} Change and Solar Cell Performance

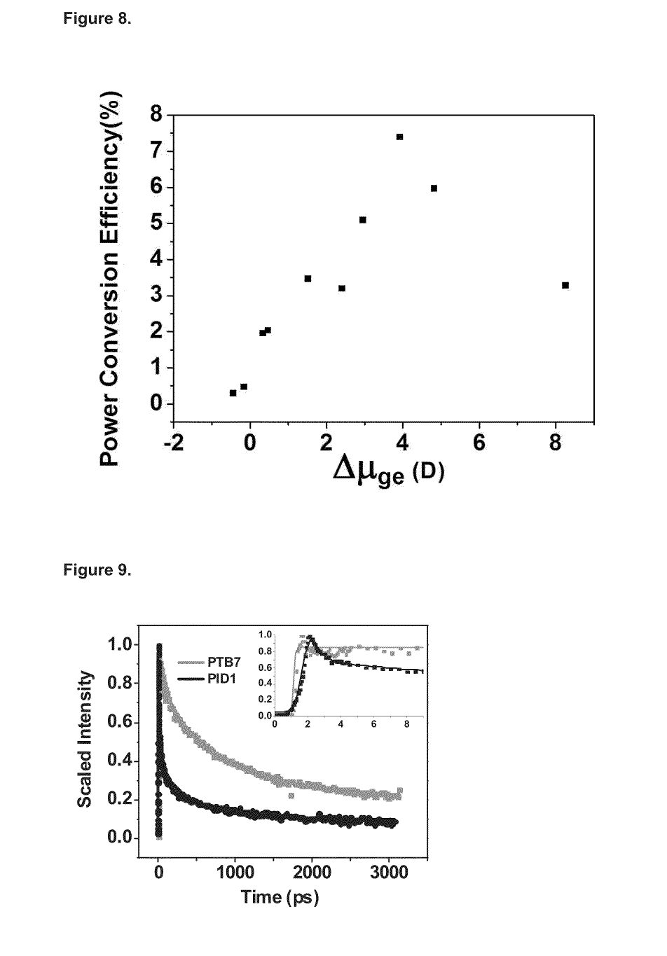

The results shown are those for the optimized solar cells and therefore it is believable to use them to compare with other similarly optimized systems. The dipole moments of single repeating units in PID1 and PPB1 were calculated using the procedure in our previous study. The results are presented together with the optimized power conversion efficiency (PCE) values in Table 5 along with data for other polymers previously reported. To simulate the randomized orientation of the asymmetric TID unit, the average dipole moment for each polymer repeating unit was determined and used for the analysis of dependence of PCE values on dipole changes. Both the ground and excited state dipole moments were calculated for each polymer repeating unit in the series. The overall change Δμ_{ge} was calculated by accounting for the changes of the dipole along each coordinate axis. Researches indicated that a linear correlation between Δμ_{ge} and PCEs exists, where the PTB7 showed the highest values of both PCE (7.4%) and Δμ_{ge} (3.92 D). Such a trend was explained as an indication of local electron density gradient that defrays a part of the exciton binding energy, which enabled the cation generation in these polymers via intra-chain charge transfer even in solution. However, the results shown here indicate that further increasing Δμ_{ge} actually lowers PCE in the corresponding solar cell. PPB1 has a larger Δμ_{ge}, but a lower PCE value of 5.97% than PTB7. The most notable dipole moment change Δμ_{ge} comes from the TID-based polymer PID1 which is almost twice as large as PTB7. However, it exhibits a PCE value only slightly above 3%, indicating that the linear relationship of Δμ_{ge} vs PCE did not extend (FIG. 8) into the larger Δμ_{ge} regime.

TABLE 5
Calculated Single Repeating Unit Dipole Moments and the Corresponding
Optimized PCE Values.

| Polymers | μ_{g} (D) | μₑ (D) | Δμ_{ge} (D) | PCE (%) |
|---|---|---|---|---|
| PTB2 | 3.60 | 6.37 | 2.96 | 5.10 |
| PTB7 | 3.76 | 7.13 | 3.92 | 7.40 |
| PTBF2 | 3.35 | 5.45 | 2.41 | 3.20 |
| PBB3 | 0.61 | 0.82 | 0.47 | 2.04 |
| PBIT1 | 4.46 | 4.80 | 0.34 | 1.96 |
| PBIT3 | 6.99 | 6.83 | −0.16 | 0.47 |
| PBTZ1 | 0.88 | 2.41 | 1.52 | 3.46 |
| PBTZ2 | 1.92 | 1.48 | −0.44 | 0.29 |
| PPB1 | 3.58 | 7.60 | 4.82 | 5.97 |
| PID1 | 4.69 | 12.08 | 8.26 | 3.28 |

To explain these trends, one can reason that a higher Δμ_{ge} implies a larger displacement of hole-electron pair in an exciton, lower Coulombic interactions between charges, and hence a reduced exciton binding energy. In addition, the introduction of strong electron withdrawing group simultaneously enhances the polarizability of excitons and lowers the polymer LUMO energy level. Ideally, the polarized exciton facilitates an electron transfer from the polymer blocks with lower electron affinity to the adjacent blocks with higher electron affinity and then to fullerene. However, the sulfonyl group exhibits strong electron accepting ability, leading to a much larger Δμ_{ge} (8.26 D) than PTB7 (3.92 D) and a highly polarized exciton with a larger effective separation of charges within a polymer repeating unit and beyond. When Δμ_{ge} is too large, the polarized polymer repeating units could also acts as trapping or recombination centers for electrons and compete with the electron injection to the fullerene. This happens in the PPB and PID series of polymers, particularly PID1, with LUMO energy nearly 0.24 eV lower than that of PTB7. Ultrafast spectroscopic results, taken at 840 nm at which the cationic state absorption of the PID or PPB polymer in blended films dominates, confirmed this hypothesis. Although the rising time of the PID1 cation signal is still nearly 1 ps, the intramolecular charge separation (CS) dynamics in PID1 are slower than those of PTB7. The charge recombination (CR) of the cationic state, however, is relatively fast for the PID1 polymer. The CR traces of the PID1 polymer were fit to a tri-exponential decay of 2 ps, 60 ps, and >2 ns. At 3 ns, the cationic signal of only <10% remains, which is much smaller than those in PTB7 (FIG. 9). The increased recombination rate is attributed to the increased binding energy of the bound charge transfer state within the polymer, which enhance the recombination probability. These results seem to indicate that the TID unit is too strong in electron-withdrawing ability to be useful in heteropolymers used as donor materials. An optimized polarizability in polymer repeating units is achieved with a Δμ_{ge} around 4 Debye.

Device and material studies on a low bandgap polymer PID with an extraordinarily large dipole moment change Δμ_{ge} extends previous researches of the effect of internal dipole moments on the photovoltaic properties of BHJ solar cells. The sulfonyl group in new TID moiety not only resulted in a large Δμ_{ge} in the repeating unit, but also lowered the HOMO/LUMO energy levels of the corresponding polymers. It is shown that the previously observed positive linear correlation between the parameter Δμ_{ge} and PCE values might reverse as the Δμ_{ge} further increases. One of the possible reasons is that the stronger electron withdrawing group could create electron trapping or recombination centers, which would diminish the solar cell performance. A general strategy is that in order to match with the fullerene acceptor, a donor polymer with a Δμ_{ge} around 4 Debye is desirable.

### 3. Optical and Electrical Properties of Polymer Blends and Solar Cells

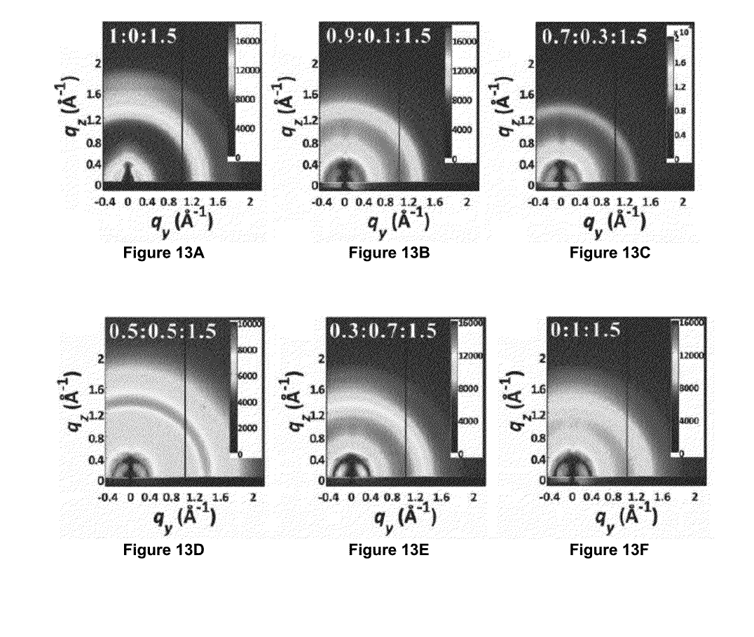

The photovoltaic properties of the polymers and compositions of some embodiments were examined when provided in polymer solar cells. Solar cells have power conversion efficiency (PCEs) larger than 8% by incorporating poly-3-oxothieno[3,4-d]isothiazole 1,1-dioxide/benzodithiophene (PID2) as the additional donor material into (PTB10):(PC₇₁BM) or (PTB7):(PC₇₁BM) host binary blend. Poly-3-oxothieno[3,4-d]isothiazole 1,1-dioxide/benzodithiophene (PID2) is also acronymed PIB2 in FIGS. 13A-13F, 14, and 16.

Without being bound by theory, the enhancement in observed power conversion efficiency may be attributable to extended light harvesting in solar spectrum by a third component, PID2. The third component not only improves photon absorption range, but may also facilitate charge separation and transport while suppressing charge recombination through a combination of cascade energy levels and optimized device morphology.

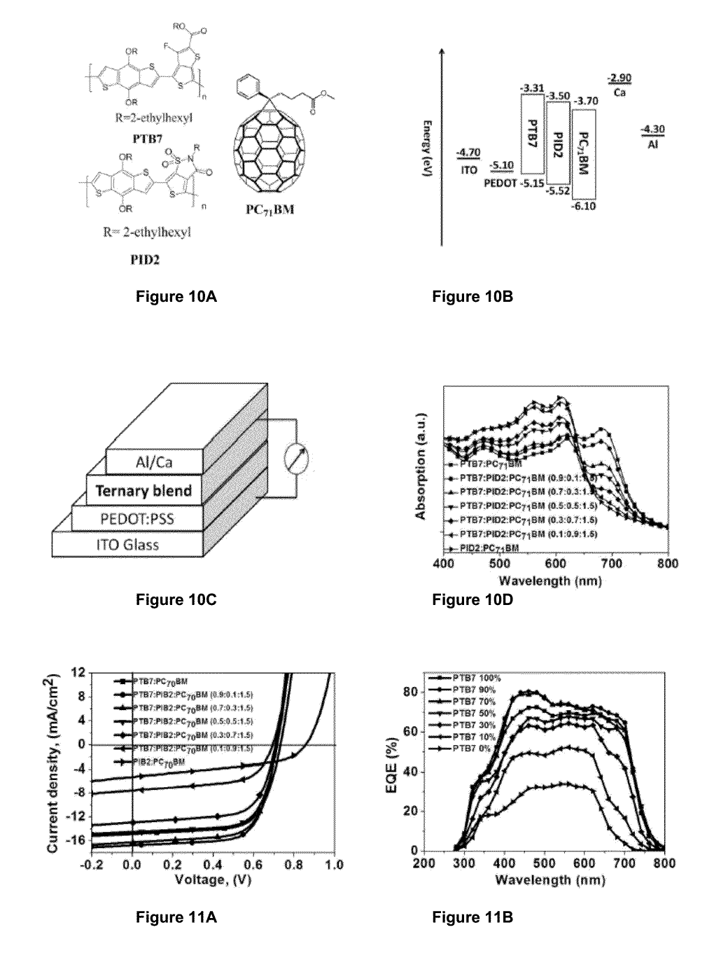

Chemical structures of PTB7, PID2 and PC₇₁BM are shown in FIG. 10A. A comparison of the cascade energy levels of the three components are shown in FIG. 10B. Solar cells used in this comparison have a simple structure that is commonly used to evaluate the material's properties: ITO/poly(3,4-ethylenedioxythiophene):poly(styrene-sulfonate) (PEDOT:PSS)/PTB7:PID2:PC₇₁BM/Ca/Al (FIG. 10C).

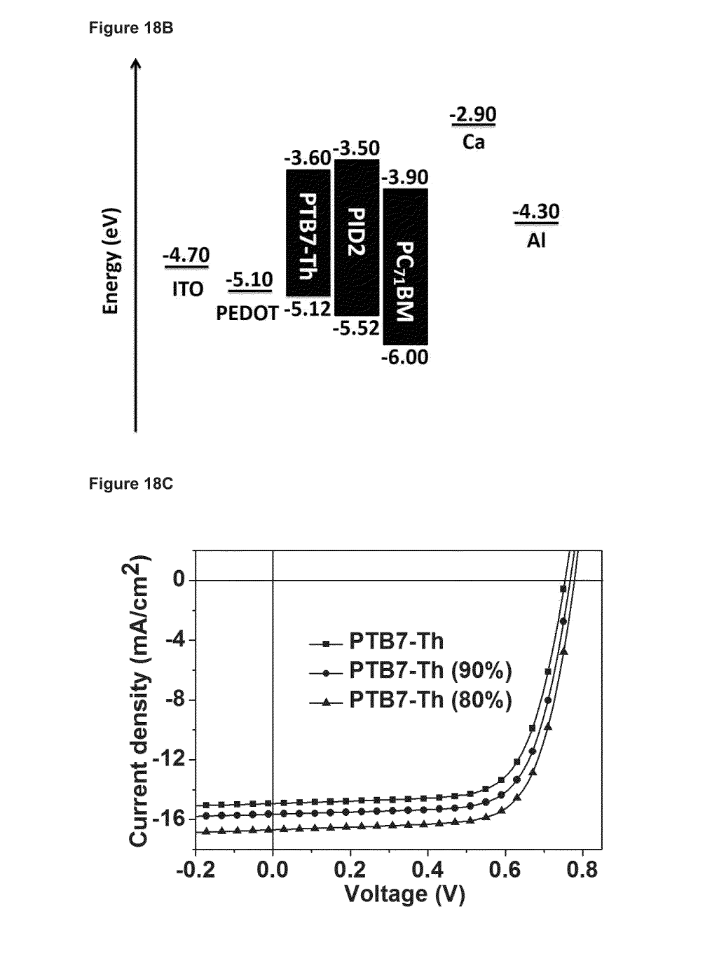

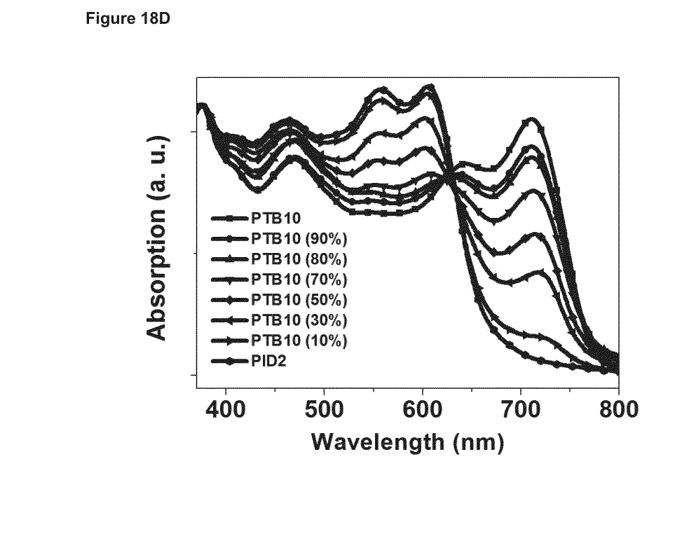

Chemical structures of PTB7-Th, PID2 and PC₇₁BM are shown in FIG. 18A. A comparison of the cascade energy levels of the three components are shown in FIG. 18B. Solar cells used in this comparison have a simple structure that is commonly used to evaluate the material's properties: ITO/poly(3,4-ethylenedioxythiophene):poly(styrene-sulfonate) (PEDOT:PSS)/PTB7-Th:PID2:PC₇₁BM/Ca/Al.

3.1. UV-Vis Absorption of Blends

The UV-vis absorption of the ternary blends with different PID2 contents was measured to study the changes in absorption upon incorporation of the third component. FIG. 10D indicates that increasing the content of PID2 in PTB7:PC₇₁BM host blend gradually enhanced the absorption from 450 nm to 650 nm while simultaneously decreased the absorption from 650 nm to 750 nm, consistent with the fact that the PID2 showed maximum absorption at 610 nm and the absorption maximum of PTB7 was at 683 nm.

The UV-vis absorption of the ternary blends with different PID2 contents was measured to study the changes in absorption upon incorporation of the third component. FIG. 18D indicates that increasing the content of PID2 in PTB7-Th:PC₇₁BM host blend gradually enhanced the absorption from 450 nm to 650 nm while simultaneously decreased the absorption from 650 nm to 750 nm, consistent with the fact that the PID2 showed maximum absorption at 610 nm and the absorption maximum of PTB7-Th was at 683 nm.

3.2. Device Parameters

3.2.1. Electrical Characteristics and Power Conversion Efficiency

3.2.1.1. PTB7:PID2:PC₇₁BM

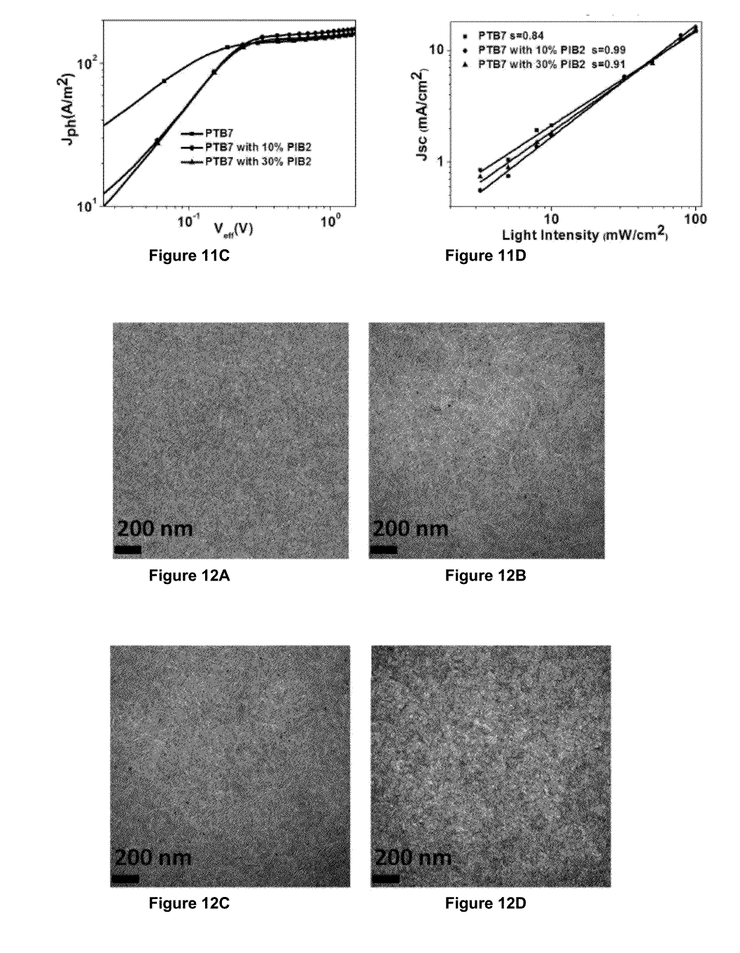

In some embodiments, the overall donor polymers to PC₇₁BM ratio was at about 1:1.5. FIG. 11A shows the corresponding current density versus voltage (J-V) characteristics of ternary blend solar cells with different PID2 contents under AM 1.5 G illumination at 100 mW/cm².

Table 6 summarizes the photovoltaic parameters for some devices. The PTB7:PC₇₁BM used as a reference device gave a power conversion efficiency (PCE) of 7.25% with an open circuit voltage (V_{oc}) at 0.72 V, a short circuit current density (J_{sc}) at 15.0 mA/cm² and a fill factor (FF) at 67.1%. FIG. 11A shows that J_{sc} was enhanced significantly after the incorporation of a small amount of PID2 (10% or 30%) into the host blend and decreased later when PID2 became the dominating donor polymer in the system. The decreased performance at high PID2 content should be ascribed to the poor performance of PID2, which only provided a power conversion efficiency (PCE) of 2.01% when mixed with PC₇₁BM. Meanwhile, V_{oc} of the ternary blend solar cells was pinned to the smaller V_{oc} of PTB7:PC₇₁BM host blend at all PID2 contents. This is attributed to the fact that V_{oc} is mainly determined by the smallest difference between the highest occupied molecular orbital (HOMO) energy levels of donor materials and lowest unoccupied molecular orbital (LUMO) energy level of PC₇₁BM. The HOMO energy levels of PTB7 and PID2 are −5.15 eV and −5.52 eV, respectively (FIG. 10B). In particular, with a 9:1 ratio between PTB7 and PID2, a J_{sc} is at 16.8 mA/cm², V_{oc} at 0.72 V and a FF at 68.7%, resulted in a very promising power conversion efficiency (PCE) of 8.22%. An average power conversion efficiency (PCE) of 8.01% was attained over 10 identical devices under this condition with a mean V_{oc} at 0.71±0.01 V, a J_{sc} at 16.7±0.36 mA/cm² and a fill factor (FF) at 67.9±0.70%. When the content of PID2 was increased to 30%, J_{sc} of the device was improved to 16.3 mA/cm², yielding a power conversion efficiency (PCE) of 7.88%. Solar cell with 50% of PID2 showed comparable power conversion efficiency (PCE) compared to the reference device. Further increasing the content of PID2 beyond 50% resulted in decreased solar cell performance due to inferior J_{sc} and fill factor (FF) compared to PTB7:PC₇₁BM reference device. Since incorporation of 10% and 30% PID2 showed better solar cell performance than the reference device, these two conditions are used in the following measurements to unravel the mechanism for the increase in J_{sc} and fill factor (FF) in ternary blend systems.

TABLE 6
Summary of solar cell parameters of ternary PTB7:PID2:PC71BM blend
with different ratios of PTB7:PID2.

| PTB7:PID2:PC₇₁BM | J_{sc} (mA/cm²) | V_{oc} (V) | FF (%) | PCE (%) |
|---|---|---|---|---|
| 1:0:1.5 | 15.0 | 0.72 | 67.1 | 7.25 |
| 0.9:0.1:1.5 | 16.8 | 0.72 | 68.7 | 8.22 |
| 0.7:0.3:1.5 | 16.3 | 0.71 | 68.0 | 7.88 |
| 0.5:0.5:1.5 | 14.5 | 0.72 | 68.3 | 7.10 |
| 0.3:0.7:1.5 | 12.9 | 0.71 | 66.1 | 6.04 |
| 0.1:0.9:1.5 | 7.56 | 0.70 | 59.5 | 3.12 |
| 0:1:1.5 | 5.27 | 0.86 | 44.4 | 2.01 |

3.2.1.2. PTB10:PID2:PC71BM

Table 7 summarizes the photovoltaic parameters for some devices including PTB10:PID2:PC71BM blend. The PID2:PC₇₁BM used as a reference device gave a power conversion efficiency (PCE) of 2.01% with an open circuit voltage (V_{oc}) at 0.858 V, a short circuit current density (J_{sc}) at 5.29 mA/cm² and a fill factor (FF) at 44.3%.

J_{sc} was enhanced after the incorporation of PTB10 (30% to 90%) into the host blend. In particular, with a 8:2 ratio between PTB10 and PID2, a J_{sc} is at 16.39 mA/cm², V_{oc} at 0.778 V and a FF at 70.2%, resulted in a very promising power conversion efficiency (PCE) of 8.94%.

TABLE 7
Summary of solar cell parameters of ternary PTB10:PID2:PC71BM
blend with different ratios of PTB10:PID2.

| PTB10:PID2:PC₇₁BM | J_{sc} (mA/cm²) | V_{oc} (V) | FF (%) | PCE (%) |
|---|---|---|---|---|
| 1:0:1.5 | 14.92 | 0.751 | 70.3 | 7.88 |
| 0.9:0.1:1.5 | 15.60 | 0.767 | 70.9 | 8.51 |
| 0.8:0.2:1.5 | 16.39 | 0.778 | 70.2 | 8.94 |
| 0.7:0.3:1.5 | 14.04 | 0.791 | 71.6 | 7.95 |
| 0.5:0.5:1.5 | 13.07 | 0.804 | 71.9 | 7.55 |
| 0.3:0.7:1.5 | 11.50 | 0.831 | 69.9 | 6.68 |
| 0.1:0.9:1.5 | 5.88 | 0.858 | 57.5 | 2.90 |
| 0:1:1.5 | 5.29 | 0.858 | 44.3 | 2.01 |

3.2.1.3. PTB7-Th:PID2:PC₇₁BM

Table 8 summarizes the photovoltaic parameters for some devices including PTB7-Th:PID2:PC₇₁BM blend. The PID2:PC₇₁BM used as a reference device gave a power conversion efficiency (PCE) of 2.01% with an open circuit voltage (V_{oc}) at 0.858 V, a short circuit current density (J_{sc}) at 5.29 mA/cm² and a fill factor (FF) at 44.3%.

J_{sc} was enhanced after the incorporation of PTB7-Th (30% to 90%) into the host blend. In particular, with a 8:2 ratio between PTB7-Th and PID2, a J_{sc} is at 16.68 mA/cm², V_{oc} at 0.78 V and a FF at 70.8%, resulted in a very promising power conversion efficiency (PCE) of 9.20%.

TABLE 8
Summary of solar cell parameters of ternary PTB7-Th:PID2:PC₇₁BM
blend with different ratios of PTB7-Th:PID2.

| PTB10:PID2:PC₇₁BM | J_{sc}(mA/cm²) | V_{oc} (V) | FF (%) | PCE (%) |
|---|---|---|---|---|
| 1:0:1.5 | 14.92 | 0.75 | 70.3 | 7.88 |
| 0.9:0.1:1.5 | 15.60 | 0.77 | 70.9 | 8.51 |
| 0.8:0.2:1.5 | 16.68 | 0.78 | 70.8 | 9.20 |
| 0.7:0.3:1.5 | 14.04 | 0.79 | 71.6 | 7.95 |
| 0.5:0.5:1.5 | 13.07 | 0.80 | 71.9 | 7.55 |
| 0.3:0.7:1.5 | 11.50 | 0.83 | 69.9 | 6.68 |
| 0.1:0.9:1.5 | 5.88 | 0.86 | 57.5 | 2.90 |
| 0:1:1.5 | 5.29 | 0.86 | 44.3 | 2.01 |

3.2.2. External Quantum Efficiency

External Quantum Efficiency (EQE) is the ratio of the number of charge carriers collected by the solar cell to the number of photons of a given energy shining on the solar cell from outside. To study changes in the short circuit current density J_{sc}, external quantum efficiency (EQE) of the ternary blend devices was measured and the results are illustrated in FIG. 11B. Unlike the trend we observed in the UV-vis absorption spectra, incorporation of 10% PID2 into PTB7:PC₇₁BM blend leads to increased EQE values over the whole wavelength region. The EQE values were enhanced most in the region between 400 nm to 550 nm where PC₇₁BM exhibits high absorption. Since incorporation of 10% PID2 only lead to better absorption from 500 nm to 620 nm in FIG. 10D, the increase in EQE between 400 nm to 550 nm at low PID2 content should not result from additional absorption enhancement of PID2. Instead, this result indicated that the small amount of PID2 played the role of hole relay between PC₇₁BM and PTB7 via its HOMO orbital. The energy diagram clearly showed that the HOMO energy level difference between PC₇₁BM and PTB7 is about 0.95 eV, too large for an effective hole transfer. The HOMO energy level of PID2 is almost positioned in the middle of the PTB7 and PC₇₁BM, forming the cascade HOMO energy levels for more effective extraction of holes from PC₇₁BM (FIG. 10B). This is further reinforced by an improved EQE values from 400 nm to 650 nm while remained similar values from 650 nm to 750 nm when PID2 content was increased to 30%. The integrated J_{sc} values from EQE spectrum for PTB7:PC₇₁BM (1.0:1.5), PTB7:PID2:PC₇₁BM (0.9:0.1:1.5), PTB7:PID2:PC₇₁BM (0.7:0.3:1.5) devices were 15.1 mA/cm², 16.3 mA/cm², 15.8 mA/cm², respectively. This is within 3% difference from measured J_{sc} values. In addition, since devices with low PID2 content (10% and 30%) showed higher or comparable EQE vales from 650 nm to 750 nm compared to the PTB7: PC₇₁BM while higher PID2 content (>30%) lead to lower EQE values from 400 nm to 650 nm, changes in light absorption may not be the only cause for J_{sc} changes in the disclosed ternary blend system, the cascade energy levels is also important to PCE changes.

3.2.3. Saturation Current Density and Charge Dissociation Probabilities

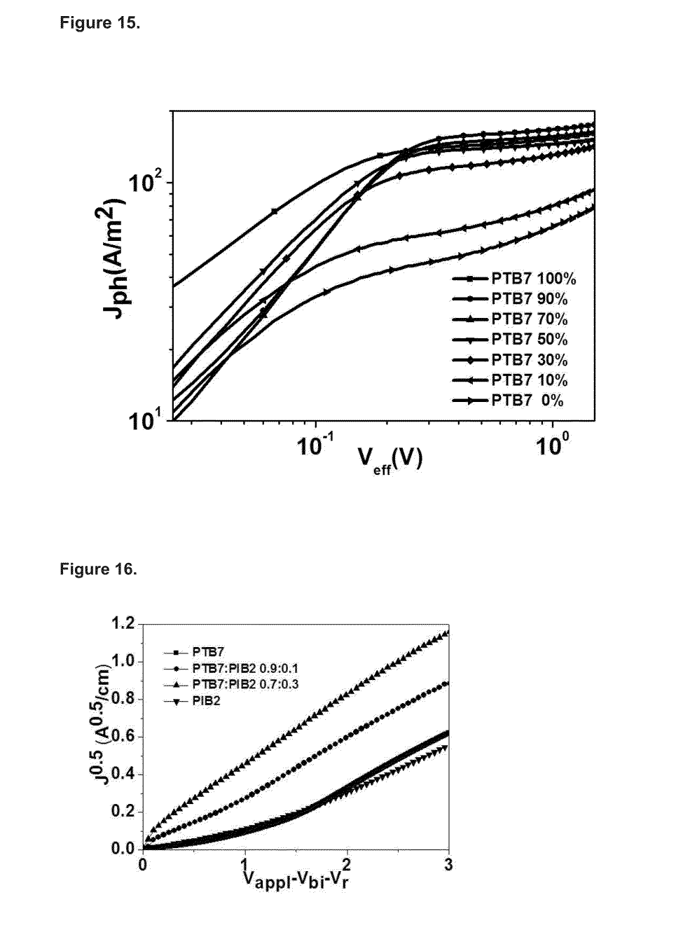

To gain more insight into light absorption and exciton dissociation process, the saturation current density (Jₛₐₜ) and charge dissociation probabilities P(E, T) of PTB7:PC₇₁BM (1:1.5), PTB7:PID2:PC₇₁BM (0.9:0.1:1.5), PTB7:PID2:PC₇₁BM (0.7:0.3:1.5) devices were determined. FIG. 11C reveals photocurrent density (Jₚₕ) versus effective voltage (V_{eff}) curves for solar cells used in this disclosure. Here Jₚₕ is defined as Jₚₕ=J_{L}−J_{D}, where J_{L} and J_{D} are the photocurrent densities under illumination and in the dark, respectively. V_{eff} is defined as V_{eff}=V₀−Vₐ, where V₀ is the voltage where Jₚₕ equals zero and Vₐ is the applied bias voltage. If assuming that all the photogenerated excitons are dissociated into free charge carriers and collected by electrodes at a high V_{eff} (i.e. V_{eff}=2 V), saturation current density (Jₛₐₜ) will only be limited by total amount of absorbed incident photons. The Jₛₐₜ values for the three devices were 169 A m⁻² (0% PID2 content), 180 A m⁻² (10% PID2 content) and 169 A m⁻² (30% PID2 content), respectively. Further increasing the content of PID2 showed dramatic decrease in Jₛₐₜ values (FIG. 15). The larger Jₛₐₜ value of device with 10% PID2 content would suggest enlarged overall exciton generation while the unchanged Jₛₐₜ value of device with 30% PID2 content suggested the same overall exciton generation compared to the control device. It should be pointed out that even though Jₛₐₜ increased at 10% PID2 content by 6.5%, the increased Jₛₐₜ was still not enough to account for the overall enhancement in J_{sc} (12%). Since both 10% and 30% contents of PID2 showed much larger J_{sc} values than the control device, the Jₚₕ results further confirmed the assertion that both absorption change and energy cascade contributed to the change in current density in this disclosure. The P(E, T) is determined by normalizing Jₚₕ with Jₛₐₜ (Jₚₕ/Jₛₐₜ) The P(E, T) values under J_{sc} condition for the three devices were 88.0%, 90.2%, 91.2%, respectively, while the P(E, T) value for PID2:PC₇₁BM device was only 65.6%. The results showed that incorporation of PID2 at low contents facilitated charge dissociation in ternary devices.

3.2.4. Dependence of Short Circuit Current Density on Light Intensity

In addition to light absorption and exciton dissociation, we also measured the short circuit current density J_{sc} as a function of illumination intensities for the films of three compositions to monitor the changes in recombination kinetics. Quantitatively, J_{sc} follows a power-law dependence on light intensity (J_{sc}∝P_{light}^{S}). In general, linear scaling of photocurrent with P_{light} would suggest weak bimolecular recombination while sublinear scaling of photocurrent with P_{light} indicates partial loss of charge carriers during charge transport process due to bimolecular recombination. As shown in FIG. 11D, the exponential factors of PTB7:PC₇₁BM (1:1.5), PTB7:PID2:PC₇₁BM (0.9:0.1:1.5), PTB7:PID2:PC₇₁BM (0.7:0.3:1.5) devices were 0.84, 0.99, 0.91, respectively. Thus, bimolecular recombination was weakest in devices with 10% of PID2. Compared to PTB7:PC₇₁BM, device with 30% of PID2 also showed decreased bimolecular recombination. Changes in bimolecular recombination help to explain the increased J_{sc} and FF in the ternary blend system. This is in good agreement with hole mobility data of these devices, measured with the structure ITO/PEDOT:PSS/PTB7:PID2/Al using space-charge-limited current (SCLC) model. As shown in FIG. 16, hole mobility increased from 5.42×10⁻⁴ cm²V⁻¹ s⁻¹ (PTB7) to 7.75×10⁻⁴ cm² V⁻¹ s⁻¹ (PTB7:PID2/0.9:0.1) and 8.72×10⁻⁴ cm²V⁻¹s⁻¹ (PTB7:PID2/0.7:0.3), while the mobility of PID2 was only 2.71×10⁻⁴ cm²V⁻¹ s⁻¹. The improved charge transport properties may attribute to the cascade energy levels in the ternary system and improved morphology.

3.2.5. Morphology of Ternary Blend

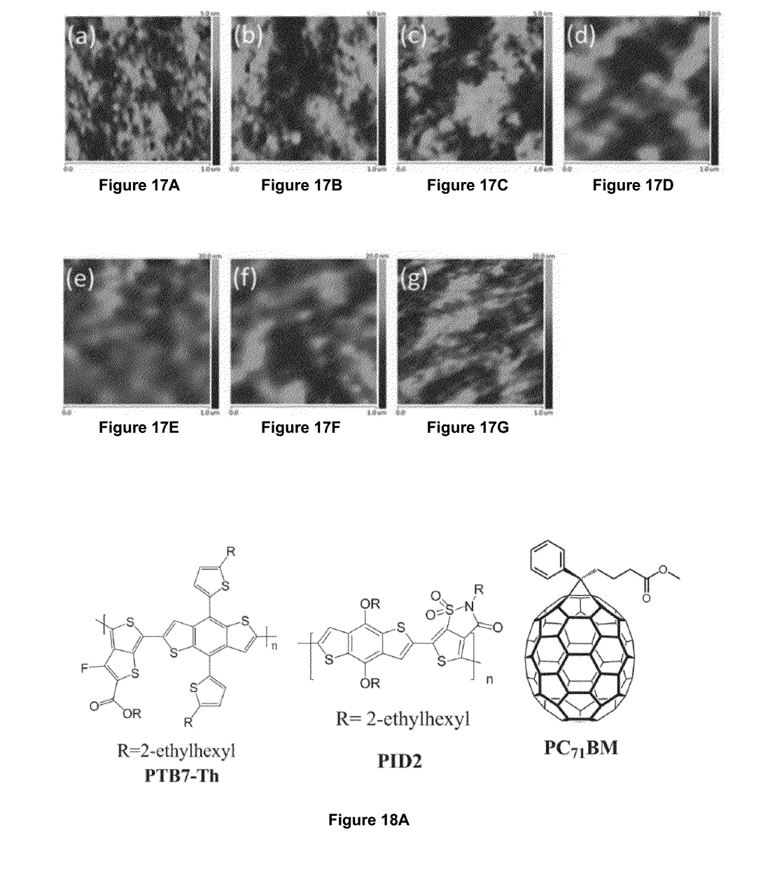

The transmission electron microscopy (TEM) was used to probe morphology of the ternary blend (FIGS. 12A-12D). Both PTB7:PID2:PC₇₁BM (0.9:0.1:1.5) and PTB7:PID2:PC₇₁BM (0.7:0.3:1.5) films showed fibrous features while no such structure was observed in PTB7:PC₇₁BM or PID2:PC₇₁BM devices. This indicates that the PID2 plays the role of template for the formation of fibrous structure in PTB7. The fine dispersed fibrils were previously found beneficial to exciton separation and charge transport. The results of tapping mode atomic force microscopy (AFM) measurements indicated the root-mean-squared (RMS) roughness of the four devices based on PTB7:PC₇₁BM (1:1.5), PTB7:PID2:PC₇₁BM (0.9:0.1:1.5), PTB7:PID2:PC₇₁BM (0.7:0.3:1.5), PID2:PC₇₁BM (1:1.5) was 0.87 nm, 1.06 nm, 1.02 nm and 2.31 nm, respectively (FIGS. 17A-17G). Although PID2 showed much higher roughness than PTB7 when mixed with PC₇₁BM, blending PID2 into PTB7:PC₇₁BM up to 30% did not cause any significant change of surface roughness of the host blend. X-ray scattering techniques helped to understand changes in molecular packing, structure ordering and domain sizes in the disclosed devices.

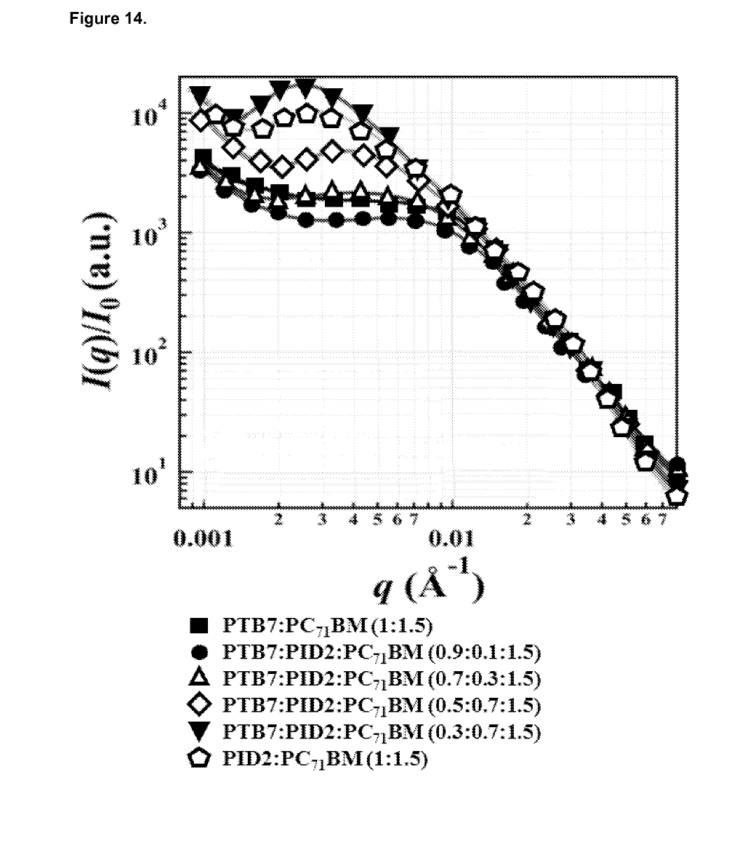

Shown in FIGS. 13A-13F and 14 are the 2D grazing incidence wide-angle X-ray scattering (GIWAXS) patterns and resonant soft X-ray scattering (RSoXS) profiles of the ternary PTB7:PID2:PC₇₁BM blend films with different PID2 content.

TABLE 9

| PTB₇:PIB2:PC₇₁BM | qᵣ (Å⁻¹) | Δqᵣ (Å⁻¹) | D_{L} (Å) | q_{z} (Å⁻¹) | Δq_{z} (Å⁻¹) | D_{L} (Å) |
|---|---|---|---|---|---|---|
| 1:0:1.5 | 0.363 ± 0.009 | 0.172 | 34.4 | — | — | — |
| 0.9:0.1:1.5 | 0.350 ± 0.009 | 0.175 | 33.8 | — | — | — |
| 0.7:0.3:1.5 | 0.332 ± 0.009 | 0.216 | 27.4 | 0.329 ± 0.009 | 0.076 | 77.7 |
| 0.5:0.5:1.5 | 0.349 ± 0.009 | 0.140 | 42.3 | 0.333 ± 0.009 | 0.046 | 128.4 |
| 0.3:0.7:1.5 | 0.344 ± 0.009 | 0.073 | 81.2 | 0.348 ± 0.009 | 0.043 | 138.8 |
| 0:1:1.5 | 0.344 ± 0.009 | 0.033 | 180.8 | 0.336 ± 0.009 | 0.041 | 145.5 |

In the 2D GIWAXS pattern of PTB7:PC₇₁BM (1:1.5) blend film (FIG. 13A), a broad arc-like scattering arising from the Bragg diffraction of periodic PTB7 layers was observed at q_{y}˜0.36 Å⁻¹, suggesting the preferential face-on conformation, whereas the 2D GIWAXS pattern of PID2:PC₇₁BM (1:1.5) blend film (FIG. 13F) exhibited a ring-like layering peak at q_{z}˜0.34 Å⁻¹ and two off-axis scattering spots located at (±0.27, 0.38) Å⁻¹, indicating the formation of PID2 bilayer ordering with a preferential edge-on orientation similar to that observed in PCDTBT. Since the full width at half maximum (FWHMs) of scattering peak, Δq, correlates to the nanocrystallite size via Scherrer equation, the narrower Δq of PID2 layering peak indicated that PID2 could form larger nanocrystallite sizes in the blend film than PTB7. Further RSoXS studies provided access to the spatial dimensions of phase-separated domains. The RSoXS profile of the PTB7:PC₇₁BM blend film showed a diffuse scattering at q˜0.006 Å⁻¹, while that of the PID2:PC₇₁BM blend film exhibited a well-defined peak centered at a larger q value of ˜0.003 Å⁻¹ (FIG. 14). This illustrates that the phase-separated domains in PID2:PC₇₁BM blend film were larger than those in PTB7:PC₇₁BM blend film. However, upon incorporating a small amount of PID2 copolymers into PTB7:PC₇₁BM blend film (PTB7:PID2:PC₇₁BM (0.9:0.1:1.5)), PID2 copolymers showed little influence on the crystalline structures of both conjugated polymers and PC₇₁BM while induced the formation of smaller phase separated domains. These smaller domains would increase the area of interfaces between polymer donors and fullerene acceptors, thus facilitating exciton dissociation and lead to an improved performance. This is in accordance with our exciton dissociation results. Further increasing the amount of PID2 copolymers, PID2:PC₇₁BM blends gradually phase separated out of the PTB7:PC₇₁BM blends and formed individual blend region in the films. Both larger conjugated polymer nanocrystallites and phase-separated domains formed in the ternary blend films and low PID2 mobility resulted in decreased device efficiency at high PID2 content. Taken together, these observations of morphological changes in the ternary blend films support the hypothesis that the incorporation of PID2 at low contents could facilitate charge dissociation and transport. This also helps to explain the tendency of performance change as a function of the PID2 contents in our device.

In conclusion, a novel BHJ ternary solar cell system was developed by incorporating PID2 into PTB7:PC₇₁BM host blend with improved efficiency. In comparison to the control device, ternary blend solar cell with 10% of PID2 showed highest PCE at 8.22% mainly due to improved light harvest, energy level cascading and device morphology. It was found that the use of PID2 at low content lead to favorable fibrillar structures and smaller domain sizes of the control device. In the disclosed ternary system, charge recombination is suppressed while charge dissociation and transport are improved at low PID2 content due to more effective charge extraction and smaller domain sizes.

3.2.6. Methods

Device Fabrication. The polymers and PC71BM were co-dissolved in chlorobenzene and 1, 8-diodooctane (97:3, v/v). The overall polymer concentration was 10 mg/mL and the solution was stirred at 90° C. for 12 hours under N₂ atmosphere. Indium tin oxide (ITO) glass substrate was cleaned in water, acetone and isopropyl alcohol for 15 minutes under sonication. After that, glasses were exposed to ultraviolet ozone irradiation for 60 minutes. A thin layer (˜40 nm) of poly(3,4-ethylenedioxythiophene):poly(styrenesulfonate) (PEDOT:PSS) was spin-coated at 6000 rpm for 1 minute onto ITO glasses and dried at 80° C. in N₂ for 30 minutes. Active layers were spin coated using the as-prepared solutions at 2800 rpm in glove box. Ca (20 nm) and Al (80 nm) cathodes were thermal evaporated in glove box at a chamber pressure of ˜5.0×10⁻¹ torr. The area of the solar cell is 3.14 mm².

Solar Cell Characterization.

J-V characteristics of solar cells were measured under 1-sun, AM 1.5G irradiation (100 mW/cm²) from a solar simulator with a Xe lamp. Atomic force microscopy (AFM) images were obtained by using an Asylum model number MFP-3D AFM. UV-Vis spectra were taken using a UV-2401 PC model UV-Visible spectrophotometer. External Quantum Efficiency (EQE) measurement system composed of a 250 W QTH lamp as the light source, a filter wheel, a chopper, a monochromator, a lock-in amplifier and a calibrated silicon photodetector. Grazing Incidence Wide-Angle X-ray Scattering (GIWAXS) measurements were performed at the 8ID-E beamline at the Advanced Photon Source (APS), Argonne National Laboratory using x-rays with a wavelength of I=1.6868 Å and a beam size of ˜200 μm (h) and 20 μm (v).

Grazing Incidence Wide-Angle X-Ray Scattering (GIWAXS)

GIWAXS measurements were performed at the 8ID-E beamline at the Advanced Photon Source (APS), Argonne National Laboratory using x-rays with a wavelength of I=1.6868 Å and a beam size of ˜200 μm (h) and 20 μm (v). To make the results comparable to those of Organic Photovoltaic (OPV) devices, the samples for the measurements were prepared on PEDOT:PSS modified Si substrates under the same conditions as those used for fabrication of solar cell devices. A 2-D PILATUS 1M-F detector was used to capture the scattering patterns and was situated at 208.7 mm from samples. Typical GISAXS patterns were taken at an incidence angle of 0.20°, above the critical angles of PTB7 and PID2 polymers or PTB7:PID2:PC71 BM blends and below the critical angle of the silicon substrate. Consequently, the entire structure of thin films could be detected. The raw scattering intensity was corrected for solid angle correction, efficiency correction for medium (e.g. air) attenuation and detector sensor absorption, polarization correction, flat field correction for removing artifacts caused by variations in the pixel-to pixel sensitivity of the detector by use of the GIXSGUI package provided by the Advanced Photon Source (APS) at Argonne National Laboratory. In addition, the q_{y} linecut was obtained from a linecut across the reflection beam center, while the q_{z} linecut was achieved by a linecut at q_{y}=0 Å-1 using the reflected beam center as zero the silicon substrate. Consequently, the entire structure of thin films could be detected. In addition, the q_{y} linecut was obtained from a linecut across the reflection beam center. The background of these linecuts was estimated by fitting an exponential function and the parameters of the scattering peaks were obtained through the best fitting using the Pseudo-Voigt type 1 peak function.

Resonant Soft X-Ray Scattering (RSoXS)

RSoXS transmission measurements were achieved at beamline 11.0.1.2 at the Advanced Light Source (ALS), Lawrence Berkeley National Laboratory. The elliptically polarized undulator (EPU) source provides high x-ray and full polarization control. The energy of the incident beam can be tuned using a variable-line-space, plane grating monochromator providing soft x-rays in the spectral range from 100 to 1500 eV and the resolving power (E/AE) of ˜4000. The beam size at the sample position was ˜100 μm×100 μm. The RSoXS chamber was operated at high vacuum (˜10⁻⁷ Torr) and controlled by LabVIEW software developed at ALS. RSoXS was taken with x-ray photon energy of 284.4 eV for the best contrast and sensitivity. A customized designed 4-bounce higher order light suppressor was utilized to suppress higher order light generated from the undulator harmonics and monochromator. The spectral purity of the x-ray photons was higher than 99.99%. Samples for RSoXS measurements were first prepared on a PEDOT:PSS modified Si substrate under the same conditions as those used for fabrication of OPV devices, and then transferred to a 1 mm×1 mm, 100 nm thick Si₃N₄ membrane supported by a 5 mm×5 mm, 200 μm thick Si frame (Norcada Inc.). Single quadrant 2-D scattering patterns were collected on an in-vacuum CCD camera (Princeton Instrument PI-MTE). The scattering patterns were radially averaged and the scattering intensity I(q) in arbitrary units after correcting for background scattering recorded from a blank Si₃N₄ window and normalizing to the incident beam intensity 10 was plotted against the magnitude of scattering vector, q=4π sin(θ/2)/λ (where θ is the scattering angle and λ is the wavelength of the soft x-rays), on a log-linear scale.

1. A polymer of formula (I): 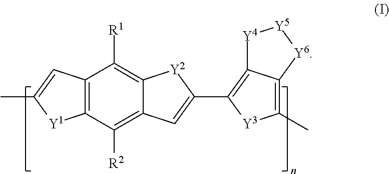
wherein Y¹, Y², Y³, Y⁴, Y⁵, and Y⁶ are independently selected from the group consisting of O, S, Se, NR³, S(O), S(O)₂, CR⁴R⁵ and C(O);
R¹, R², R³, R⁴ and R⁵ are independently selected from the group consisting of hydrogen, halogen, unsubstituted or substituted alkyl, unsubstituted or substituted alkoxy, unsubstituted or substituted aryl, unsubstituted or substituted aryloxy, unsubstituted or substituted heteroaryl, and unsubstituted or substituted heteroaryloxy; and
n is an integer greater than 0.

2. The polymer of claim 1, wherein R¹ and R² are independently C₁₋₃₀ alkoxy.

3. The polymer of claim 1, wherein R¹ and R² are independently 2-ethylhexyloxy.

4. The polymer of claim 1, wherein Y¹, Y², and Y³ are independently S.

5. The polymer of claim 1, wherein Y⁴ is S(O)₂.

6. The polymer of claim 1, wherein Y⁵ is NR³.

7. The polymer of claim 1, wherein R³ is C₁₋₃₀ alkyl.

8. The polymer of claim 1, wherein R³ is 2-ethylhexyl.

9. The polymer of claim 1, wherein R³ is octyl.

10. The polymer of claim 1, wherein Y⁶ is C(O).

11. A polymer of formula (II): 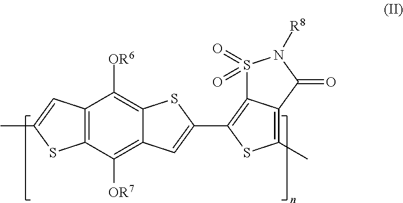
wherein R⁶, R⁷, and R⁸ are independently selected from the group consisting of hydrogen, unsubstituted or substituted alkyl, and unsubstituted or substituted aryl; and
n is an integer greater than 0.

12. The polymer of claim 11, wherein R⁶, R⁷, and R⁸ are independently C₁₋₃₀ alkyl.

13. The polymer of claim 11, wherein R⁶, R⁷, and R⁸ are independently 2-ethylhexyl.

14. The polymer of claim 11, wherein R⁸ is octyl.

15. A composition comprising an electron-withdrawing material, an electron-donating polymer, and a polymer of formula (I): 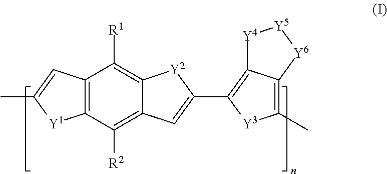
wherein Y¹, Y², Y³, Y⁴, Y⁵, and Y⁶ are independently selected from the group consisting of O, S, Se, NR³, S(O), S(O)₂, CR⁴R⁵ and C(O);
R¹, R², R³, R⁴ and R⁵ are independently selected from the group consisting of hydrogen, halogen, unsubstituted or substituted alkyl, unsubstituted or substituted alkoxy, unsubstituted or substituted aryl, unsubstituted or substituted aryloxy, unsubstituted or substituted heteroaryl, and unsubstituted or substituted heteroaryloxy; and
n is an integer greater than 0.

16. The composition of claim 15, wherein the polymer of formula (I) is further characterized as formula (II): 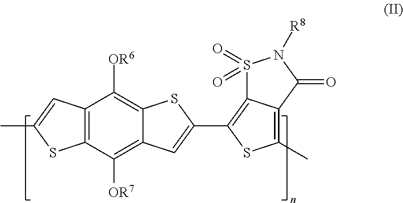
wherein R⁶, R⁷, and R⁸ are independently selected from the group consisting of hydrogen, unsubstituted or substituted alkyl, and unsubstituted or substituted aryl; and
n is an integer greater than 0.

17. The composition of claim 15, wherein the electron-withdrawing material is a fullerene derivative.

18. The composition of claim 15, wherein the electron-donating polymer is of formula (III): 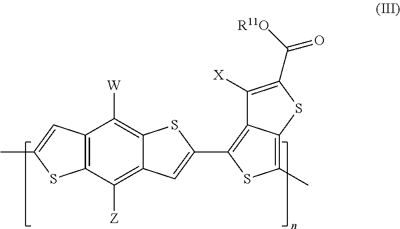
wherein W and Z are independently selected from the group consisting of hydrogen, unsubstituted or substituted alkyl, unsubstituted or substituted alkoxyl, unsubstituted or substituted cycloalkyl, unsubstituted or substituted heterocycloalkyl, unsubstituted or substituted aryl, unsubstituted or substituted aryloxyl, and unsubstituted or substituted heteroaryl;
R¹¹ is selected from the group consisting of hydrogen, unsubstituted or substituted alkyl, unsubstituted or substituted cycloalkyl, unsubstituted or substituted heterocycloalkyl, unsubstituted or substituted aryl, and unsubstituted or substituted heteroaryl;
X is selected from the group consisting of F, Cl and Br; and
n is an integer greater than 0.

19. The composition of claim 18, wherein the ratio of the polymer of formula (I) and the polymer of formula (III) to the electron-withdrawing material is in a range of about 1:0.5 to about 1:4.

20. A method of making a solar cell, an optical device, an electroluminescent device, a photovoltaic cell, semiconducting cell, or photodiode, comprising, providing a polymer of claim 1.
